(19) United States
(12) Patent Application Publication
(10) Pub. No.: US 2006/0234499 A1
(43) Pub. Date: Oct. 19, 2006

(54) Substrate processing method and substrate processing apparatus

(76) Inventors: Akira Kodera, Fujisawa-shi (JP); Hirokuni Hiyama, Fujisawa-shi (JP); Akio Shibata, Fujisawa-shi (JP); Tsutomu Nakada, Tokyo (JP); Tsuyoshi Sahoda, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/389,178

(22) Filed: Mar. 27, 2006

(30) Foreign Application Priority Data
Mar. 29, 2005 (JP) 2005-96511
Apr. 28, 2005 (JP) 2005-130850
Jun. 28, 2005 (JP) 2005-188959

(51) Int. Cl. H01L 21/4763; H01L 21/76

(52) U.S. Cl. 438/641; 438/430

(57) ABSTRACT

A substrate processing method forms a plated film which is thin and has a high flatness by covering the surface (outermost surface) of a substrate, excluding interior surfaces of recesses such as trenches, with a plating inhibiting material such as an SAM-forming molecular species. The substrate processing method comprises: preparing a substrate having recesses formed in a surface; attaching a plating inhibiting material for inhibiting plating to an outermost surface, which excludes interior surfaces of the recesses, of the substrate surface; and then carrying out electroplating of the surface of the substrate, thereby filling the recesses with a plated metal.

### BACKGROUND OF THE INVENTION

1. Field of the Invention

The present invention relates to a substrate processing method and a substrate processing apparatus, and more particularly to a substrate processing method and a substrate processing apparatus which are suited for carrying out processing of filing fine recesses, such as trenches and contact holes, formed in a surface of a substrate, such as a semiconductor wafer, with a plated metal. The present invention also relates to a substrate processing method and a substrate processing apparatus suited for carrying out metal plating in the field of semiconductor packaging, such as a chip size package (CSP) or a single in-line package (SIP).

2. Description of the Related Art

While dry processes have principally been employed conventionally for forming e.g., LSI interconnects on a semiconductor substrate, wet processes such as plating, chemical mechanical polishing (CMP), electrolytic etching, electrolytic polishing and cleaning, are being progressively employed these days. For example, a process (so-called damascene process) is being used which comprises filling, by plating, trenches and contact holes, formed in a surface of a substrate, with aluminum or, more recently, a metal (conductive material) such as copper or silver, followed by CMP to remove an extra metal and flatten the surface.

FIGS. 1A through 1C illustrate, in a sequence of process steps, a process for producing a substrate having such copper interconnects. First, as shown in FIG. 1A, an insulating film 2, for example, an oxide film of SiO₂ or a film of low-k material, is deposited on a conductive layer 1a, in which semiconductor devices has been formed, on a semiconductor base 1, and contact holes 3 and trenches 4 are formed in the insulating film 2 by the lithography/etching technique. Thereafter, a barrier layer 5 of TaN or the like is formed on the entire surface and then a seed layer 7, which serves as an electric supply layer for electroplating, is formed on the barrier layer 5 by sputtering, CVD, or the like.

In the case of CSP or SIP having deep trenches and/or holes formed in a silicone substrate, an oxide film or an insulating of e.g., polyimide is formed on surfaces of the trenches and/or holes.

Next, copper plating of the surface of the substrate W is carried out to fill the contact holes 3 and the trenches 4 with copper while depositing a copper film 6 on the insulating film 2, as shown in FIG. 1B. Thereafter, the copper film 6, the seed layer 7 and the barrier layer 5 on the insulating film 2 are removed by chemical mechanical polishing (CMP) so as to make the surface of the copper film 6, filled in the contact holes 3 and the trenches 4, substantially flush with the surface of the insulating film 2, as shown in FIG. 1C. Interconnects composed of the copper film 6 are thus formed in the insulating film 2.

FIG. 2 shows a conventional common layout of a substrate processing apparatus for carrying out electroplating. The substrate processing apparatus includes an apparatus frame 11 into which a substrate in a dry state is carried for processing from a substrate cassette housing substrates and out of which the substrate after processing is carried in a dry state. In the apparatus frame 11 are disposed a stand 12, two post-cleaning apparatuses 13 and four electroplating apparatuses 16 connected via piping 19 to a plating solution recovery apparatus 14. Also in the apparatus frame 11 are movably disposed a first substrate transport robot 18 for transferring the substrate between the substrate cassette 10 and the stand 12, and a second substrate transport robot 20 for transferring the substrate between the stand 12, one of the post-cleaning apparatuses 13 and one of the electroplating apparatuses 16.

The substrate in a dry state, which has been taken by the first substrate transport robot 18 out of the substrate cassette 10 and placed on the stand 12, is transported by the second substrate transport robot 20 to the electroplating apparatus 16, where electroplating of the substrate is carried out. The substrate after plating is transported to the post-cleaning apparatus 13, where the substrate is post-cleaned and dried, and the dried substrate is placed on the stand 12. The substrate on the stand 12 is then returned by the first substrate transport robot 18 to the substrate cassette 10 (see, for example, Japanese Patent Laid-Open Publication No. 2004-356117).

With the above-described conventional damascene process for forming interconnects of an LSI, however, there is a case in which when filling copper by plating into recesses such as contact holed and trenches, having a width of 0.01 μm to several μm, the electric fields concentrates in the interior surfaces at the openings of recesses, resulting in the formation of voids in the copper embedded in the recesses. The formation of voids is less when the trench width is large. However, even when filling copper by plating into recesses, such as trenches and holes, having a relative large trench width or hole diameter of the order of several μm to 200 μm, as employed in CSP or SIP, voids can be formed in the copper embedded in the recesses due to concentration of electrolysis in the interior surfaces at the openings of the recesses in case the aspect ratio of the trenches or holes, i.e., the depth of trenches or holes/trench width or hole diameter ratio, is high and a high current density is employed in order to shorten the plating time.

FIGS. 3A through 3D illustrate a substrate in the course of a damascene process. A substrate W is provided in which, as shown in FIG. 3A, a barrier layer 5 and a seed layer 7 are formed on a surface of an insulating film 2, such as an oxide film of SiO₂ or a film of low-k material, having recesses 8, such as trenches and contact holes, formed therein. When carrying out copper electroplating of a surface (surface to be processed) of the substrate with the recesses 8 formed therein, the electric field concentrates in the interior surfaces at the openings of the recesses 8 whereby a copper film 6 grows faster in those regions than the other region, as shown in FIGS. 3B and 3C. As a result, the openings of the recesses 8 can be closed up with the copper film 6, forming voids 9, i.e., empty spaces not filled with copper, in the copper film 6 in the recesses 8, as shown in FIG. 3D.

In the case of trenches or holes having a relatively large trench width or hole diameter and extending deep into a substrate, such as those employed in CSP or SIP, an insulating film is formed on the surfaces of the trenches or holes after they are formed. Since such trenches or holes undergo otherwise the same damascene process as described above, voids can be formed in copper embedded in the trenches or holes.

In order to avoid the formation of voids 9, it may be considered to lower the film-forming rate of the copper film 6. Lowering the film-forming rate of copper film 6, however, involves a considerably long plating time for processing trenches or holes having a large trench width or hole diameter, leading to lowering of the production efficiency.

As shown in FIG. 4A, in the case of filling copper by plating into recesses 101, such as contact holes and trenches, covered with a barrier layer 103 and formed in an insulating film 100 in a substrate and depositing a copper film 102 on an entire surface of the substrate, thereby terminating the step of plating, followed by CMP to flatten the surface of the substrate with the copper film 102 formed, dishing 104 or erosion 105, the phenomenon that part of an interconnect portion 102a of copper film 102, which is to be left, is also undesirably removed during CMP, can occur as shown in FIG. 4B. In order to avoid such a phenomenon, it is practiced to make the thickness of copper film 102 large in advance, as shown in FIG. 5.

However, though a large thickness of copper film 102 can secure flattening of a surface of copper film 102 upon completion of plating, a lot of time is needed for CMP to polish the thick copper film 102. When the plated copper film 102 is made thin, on the other hand, surface irregularities of the substrate are likely to be reflected on the surface of the copper film 102. Such a substrate, after it is processed by CMP, will leave irregularities on the polished surface. As a result, for example, an extra copper can remain unremoved, or dishing 104 or erosion 105 can occur in the interconnect regions of the substrate.

Various measures, such as the use of an additive in a plating solution, are therefore generally taken for making a plated film (copper film) formed on a substrate surface thin upon completion of a plating step and also making the surface of the plated film flat over the entire substrate at that point of time. When carrying out embedding of copper in trenches by electroplating using a plating solution whose uniform electrodeposition property and leveling property are improved by the use of an adjusted additive, there may occur the phenomenon that the thickness of plated film becomes larger in an interconnect portion than in the non-interconnect portion, or the phenomenon that the thickness of plated film becomes smaller adversely in an interconnect portion with a large interconnect width than in the non-interconnect portion, forming irregularities 102b in a surface of copper film (plated film) 102, as shown in FIG. 4A.

The term “uniform electrodeposition property” refers to the capability of a plating solution to grow a plated film having a uniform thickness, and the term “leveling property” refers to the capability of a plating solution to flatten microscopic irregularities, polishing marks, etc. of a substrate surface. Such variation in the thickness of plated film causes no problem in embedding of copper in the interconnect regions of a substrate, but makes flattening of the substrate surface in a post-plating CMP step quite difficult. Plating with a large plated film thickness, intended for reducing such variation in the thickness of plated film, leads to a prolonged processing time in a CMP step.

An electrochemical mechanical deposition (ECMD) technique is disclosed as a method for achieving copper electroplating that provides a flat plated surface (see U.S. Pat. No. 61,769,992 entitled “Method and Apparatus for Electrochemical Mechanical Deposition”). This method involves polishing with a pad of the field regions of a substrate, where copper interconnects are not formed, during deposition of copper (conductive material). This achieves preferential deposition of copper in trenches formed in the surface of the substrate while minimizing deposition of copper on the field regions, thereby producing a flat copper deposit over the entire substrate surface.

A technique of micro-contact printing of a self-assembled molecular monolayer (SAM) is known. A molecule (SAM-forming molecular species), which forms an SAM, has a functional group capable of binding to a certain type of solid. When the molecules bind to the solid, the moiety (generally a long-chain hydrocarbon) of a molecule other than the functional group, interacts with an adjacent molecule (SAM-forming molecular species) at a surface of a substrate, forming an impenetrable dense structure. Thus, because of the presence of the dense structure, other types of molecules, etc. cannot reach the outermost surface of the substrate.

A technique is disclosed which involves forming SAM by the micro-contact printing technique so as to selectively deposit a material on a semiconductor substrate by CVD or the like (see U.S. Pat. No. 6,176,992).

There is a published article reporting contact transfer of an alkanethiol, an SAM-forming molecular species, which has been applied to a silicone resin, to a substrate by micro-contact printing (see Electrochemical and Solid-State Letters, September 2004, C101-C103). According to this method, an alkanethiol is transferred in advance by micro-contact printing to the outermost surface of the substrate, i.e., the substrate surface excluding the interior surfaces of recesses such as trenches, thereby inhibiting the growth of a plated film on the outermost surface of the substrate. The article also proposes a new process for growing a copper plated film only on the interior surfaces of recesses.

According to this method, as shown in FIG. 6, in damascene copper plating the growth of copper film 102 on the outermost surface 51 of a substrate, i.e., the substrate surface excluding the interior surfaces 52 of recesses 101, is completely inhibited and the copper film 102 is filled only into the recesses 101, such as trenches, which are to become interconnect portions 102a. This can cause the problem that a post-plating heat treatment does not fully produce the intended effects, such as re-crystallization of copper, a reduction of strain of copper, etc.

In particular, according to this method, the outermost surface 51 of the surface, i.e., the substrate surface excluding the interior surfaces 52 of the recesses 101 such as trenches, which are to become interconnect portions, is fully covered with a plating inhibitor such as an SAM-forming molecular species before forming interconnects. Accordingly, as shown in FIG. 6, the copper film 102 having protruding portions 102c is formed only in the interconnect portions of the substrate surface upon completion of a plating step. This can cause the following problems in later heat treatment and CMP steps. Because of the formation of copper film 102 only in the interconnect portions, the volume of copper is relatively small, which will reduce the effects of heat treatment, such as re-crystallization of copper and a reduction of strain of copper. As is known, a certain high volume of copper is necessary for effective heat treatment with the desired effect, such as a reduction of strain of copper.

Further, the deposited copper film 102, after filling the recesses 101 such as trenches, protrudes from the substrate surface in the protruding portions 102c. Accordingly, due to a shear force applied locally during a later CMP step, separation can occur between the copper film 102 and the underlying barrier layer 103 or between the barrier layer 103 and the underlying insulating film 100 of low-k material or the like.

Though the above-described method using the micro-contact printing technique is effective for a laboratory sample of small area, it cannot uniformly process the entire surface of a silicon wafer of large area used in a recent semiconductor manufacturing process.

In order to solve this problem, it is proposed to perform uniform processing of a large-area sample by using, for example, a method comprising bringing the surface of the sample into contact with a flexible stamp whose surface is wetted with a solution containing an SAM-forming molecular species. The state of contact between the stamp and the sample surface is mechanically controlled by changing a differential pressure in the flexible stamp (see Japanese Patent Laid-Open Publication No. 9-240125). Such a mechanical control, however, makes the construction of the apparatus and its control complicated, leading to an increased cost of apparatus.

Further, a technique is disclosed which uses a stamp formed of a porous material having fine poses of 10 nm to 1 μm and provides a coating solution supply section for supplying a coating solution to the porous material, thus eliminating the need for a step of immersing the stamp in the coating solution (see Japanese Patent laid-Open Publication No. 2003-39399). This technique involves the problem that because of weak bond between a substrate and an SAM-forming molecular species in forming SAM on the surface of the substrate, it is necessary to apply the coating solution several times in order to print the SAM-forming species uniformly on the surface of the substrate. Thus, with the current micro-contact printing methods for forming an SAM on a surface, it is not possible to uniformly print an SAM-forming molecular species on a surface of a large area of more than several square centimeters with good reliability or good reproducibility.

### SUMMARY OF THE INVENTION

The present invention is directed to realizing the formation of a plated film which is thin and has a high flatness by covering a surface (outermost surface) of a substrate, excluding interior surfaces of recesses such as trenches, with a plating inhibiting material such as an SAM-forming molecular species. If a plated film, which is thin and has a high flatness, can be obtained, the processing time in a CMP step can be shortened, as described above, making it possible to realize a lower-cost semiconductor device manufacturing process.

As described above, in the conventional plating using the damascene copper plating technique, only recesses such as trenches, which are to become interconnect portions, are filled with a plated metal while completely inhibiting deposition of the plated metal on an outermost surface of a substrate, i.e., a substrate surface other than interior surfaces of the recesses. Accordingly, when carrying out heat treatment of the substrate, the effects of re-crystallization, a reduction of strain, etc. of the copper plated film formed by electroplating are lowered. Further, the strain can cause separation between copper, an underlying barrier layer, and an insulating material such as a low-k material.

The present invention is directed to solving the problem of obtaining a method which can effectively reduce strain of a copper film formed by electroplating.

As described above, the conventional micro-contact printing technique for inhibiting growth of plated film has the problem that a plating inhibiting film can not be formed uniformly over the entire surface of such a substrate as a silicon wafer of large area. The present invention is directed to solving the problem of obtaining a method which can form a plating inhibiting film uniformly over the entire surface of a large-area substrate.

When forming an SAM on a surface of a substrate, because of weak bond between the substrate and an SAM-forming molecular species, it is necessary to apply a coating solution several times in order to print the SAM-forming species uniformly on the surface of the substrate. The present invention is directed to solving the problem of obtaining a method which can strongly bond an SAM-forming molecular species to a surface of a substrate even by one-time application.

Further, the present invention is directed to providing a substrate processing apparatus and a substrate processing method which, when filling recesses, such as trenches and contact holes formed in the surface of a substrate, with a plated metal, can avoid the formation of voids in the plated metal without a decrease in the production efficiency.

In order to solve the above problems, the present invention provides a substrate processing method comprising: preparing a substrate having recesses formed in a surface; attaching a plating inhibiting material for inhibiting plating to an outermost surface, which excludes interior surfaces of the recesses, of the substrate surface; and then carrying out electroplating of the surface of the substrate, thereby filling the recesses with a plated metal.

According to the present invention, by carrying out electroplating of a substrate after covering with a plating inhibiting material (plating inhibitor) an outermost surface of the substrate, i.e., the substrate surface other than the interior side wall surfaces, bottom surfaces, etc. of recesses, such as trenches and contact holes, on which copper is to be deposited for the formation of interconnects, it becomes possible to form a plated film (plated metal), such as copper film, which fills in the recesses and which is thin and has a high surface flatness upon completion of a plating step, over the entire surface of the substrate.

Preferably, after filling in the recesses with the plated metal, the plating inhibiting material is released from the outermost surface of the substrate.

Preferably, after releasing the plating inhibiting material from the outermost surface of the substrate, additional electroplating is carried out on the surface of the substrate.

Thus, in addition to the surface of the plated film, such as a copper film, embedded in the recesses such as trenches (portions to become e.g., interconnects of a semiconductor integrated circuit), electroplating simultaneously proceeds also on the substrate surface (outermost surface) from which the plating inhibiting material has been released, and a plated film deposits with a uniform thickness over the entire surface of the substrate (on the side in which the recesses such as trenches are formed). Accordingly, by terminating electroplating when the thickness of the plated film deposited on the outermost surface of the substrate has reached a desired value, the substrate having a highly flat plated film over the entire surface can be obtained.

The present substrate processing method, which can produce such a substrate, has the following advantages:

(1) In heat treatment of a substrate carried out after plating, the deposited plated metal, such as copper, can be controlled at a uniform temperature over the entire surface of the substrate, whereby an ideal heat treatment effect can be obtained. Thus, sufficient re-crystallization and reduction of strain of the plated metal can be achieved. This can suppress the occurrence of troubles, for example, disconnection in a semiconductor chip formed on the substrate.

(2) The thickness of plated film can be made such a small value that the entire plated metal on a substrate can be heat-treated at a uniform temperature, including the temperature in the thickness direction of the plated film. This can shorten the time taken for CMP.

The plating inhibiting material may be released from the outermost surface of the substrate by a reverse-electrolysis processing with reverse polarity to that of the electroplating.

By appropriately selecting the timing and the conditions (current density, applied voltage, processing time, etc.) of the reverse-electrolysis processing, the plated film can be made to have a sufficient surface flatness upon completion of plating. This offers the following advantages in a later CMP processing:

(1) Sufficient flattening of the surface of plated film can be secured and, in addition, an extra plated film can be completely removed.

(2) There is no possibility of an excessive shear force being applied by a polishing agent, such as abrasive grains, to the copper plated film, etc. of the substrate. Therefore, above-described separation between the plated film (copper film), a barrier layer and an insulating layer can be avoided.

(3) In addition, the substrate surface has high flatness from the beginning of CMP. Accordingly, polishing of the substrate can be effected without dishing or erosion.

Besides the reverse-electrolysis processing with reverse polarity to that of the electroplating, the following methods can be used to release the plating inhibiting material from the outermost surface of the substrate:

(1) A method of releasing the plating inhibiting material from the outermost surface of the substrate in or outside a plating solution by an elastic body having such physical properties as not to damage the substrate.

(2) A method of releasing the plating inhibiting material from the outermost surface of the substrate outside a plating solution by immersing the substrate in a solution which dissolves the plating inhibiting material.

(3) A method of releasing the plating inhibiting material from the outermost surface of the substrate in or outside a plating solution by ultrasonically vibrating the surface of the substrate.

(4) A method of releasing the plating inhibiting material from the outermost surface of the substrate in or outside a plating solution by applying a water pressure to the surface of the substrate by a nozzle or the like.

Preferably, the reverse-electrolysis processing with reverse polarity to that of the electroplating is carried out when the surface of the plated metal embedded in the recesses of the substrate has become flush with the outermost surface of the substrate to which the plating inhibiting material has been attached.

Thus, when the surface of copper embedded in the recesses of the substrate has reached the same level as the outermost surface of the substrate to which the plating inhibiting material has been attached, electric field is applied in the reverse direction to that of the plating to release the plating inhibiting material from the outermost surface of the substrate.

The term “outermost surface of substrate” refers to the surface of a seed layer or a barrier layer, formed as the topmost layer in a substrate, excluding interior surfaces of recesses.

The plating inhibiting material is attached to the outermost surface of the substrate preferably by providing a stamp carrying the plating inhibiting material, and pressing the stamp against the surface of the substrate to transfer the plating inhibiting material carried on the stamp to the outermost surface of the substrate.

This makes it possible to attach the plating inhibiting material with an even thickness to the outermost surface of the substrate, thereby obtaining a flatter plated film.

The plated metal is, for example, copper, a copper alloy or silver.

The use of such a metal can provide highly-practical substrate interconnects.

The plating inhibiting material is attached to the outermost surface of the substrate preferably with a uniform thickness.

This makes it possible to inhibit the growth of plating uniformly over the entire outermost surface of the substrate and, when carrying out the reverse-electrolysis processing with reverse polarity to that of the electroplating, to uniformly release the plating inhibiting material from the outermost surface of the substrate, thus contributing to obtaining a flat surface of plated film upon completion of electroplating.

Preferably, a plating inhibiting material-carrying portion of the stamp for carrying the plating inhibiting material comprises at least one of a silicone resin and a fluorocarbon resin.

The use of such a resin has the advantage of good ink-releasability. If necessary, other material(s) may be used in combination with the resin(s) to form the plating inhibiting material-carrying portion.

Preferably, the plating inhibiting material-carrying portion is supported by a support.

According to circumstances, such as low mechanical strength of the plating inhibiting material-carrying portion, the plating inhibiting material-carrying portion may preferably be provided with a support to reinforce the mechanical strength.

At least an external surface of the plating inhibiting material-carrying portion preferably is a flat plate-like or cylindrical face.

A stamp whose plating inhibiting material carrying-portion has a flat plate-like contour is versatile because it can take rectangular, circular or any other shape of contour. A stamp whose plating inhibiting material-carrying portion has a cylindrical contour can be rotated about its axis.

In a preferred aspect of the present invention, the plating inhibiting material is attached to the outermost surface of the substrate by applying the plating inhibiting material in the form of a beam to the outermost surface approximately parallel thereto in a high-vacuum chamber at such a vacuum that the mean free path is equal to or longer than the distance from a plating inhibiting material jet orifice to the end of the substrate on the far side from the plating inhibiting material jet orifice.

This makes it possible to attach the plating inhibiting material only to the outermost surface of the substrate without the need for patterning e.g., with a resist, thus simplifying the process. Furthermore, this method enables uniform processing of even a large-area substrate. The term “in the form a beam” herein refers to such a state of the material that the material in a particulate form is flying, with particles constituting a beam, having approximately the same energy and flying approximately in the same direction.

Preferably, the plating inhibiting material is attached to the outermost surface of the substrate to form a self-assembled molecular monolayer.

By utilizing the nature of an SAM-forming molecular species of being self-assembling to form a self-assembled molecular monolayer, the plating inhibiting material can be densely attached to the outermost surface of the substrate, forming a strong film of the plating inhibiting material on the outermost surface of the substrate.

Preferably, before attaching the plating inhibiting material to the outermost surface of the substrate, a metal is vapor-deposited onto the outermost surface of the substrate from a direction approximately parallel to the surface of the substrate in a high-vacuum chamber at a such a vacuum that the mean free path is equal to or longer than the distance from a vapor deposition source to the end of the substrate on the far side from the vapor deposition source.

This makes it possible to vapor-deposit a metal thinly only on the outermost surface of the substrate without deposition of the metal on the interior surfaces of fine recesses, such as trenches. Since an SAM-forming molecular species easily adheres to the metal, the plating inhibiting material, in the form of a self-assembled molecular monolayer, can be strongly bonded to the outermost surface of the substrate, forming a uniform strong layer of the plating inhibiting material.

The metal is, for example, Au, Ag or Cu, or an alloy of two or three of the metals.

In a preferred aspect of the present invention, a metal is vapor-deposited onto the outermost surface of the substrate from a direction approximately parallel to the surface of the substrate in a high-vacuum chamber at such a vacuum that the mean free path is equal to or longer than the distance from a vapor deposition source to the end of the substrate on the far side from the vapor deposition source, and thereafter the plating inhibiting material is attached to the outermost surface of the substrate to form a self-assembled molecular monolayer.

In a preferred aspect of the present invention, the plating inhibiting material is attached to the outermost surface of the substrate by providing a stamp carrying the plating inhibiting material, and pressing the stamp against the surface of the substrate to transfer the plating inhibiting material carried on the stamp to the outermost surface of the substrate.

The plating inhibiting material can be easily transferred to the outermost surface of the substrate by this method.

Alternatively, the plating inhibiting material may be transferred to the outermost surface of the substrate by screen printing using a screen for screen printing.

The plating inhibiting material can be easily transferred to the outermost surface of the substrate also by this method.

It is preferred to use as the screen for screen printing a film composed of a mesh and a porous material.

This makes it possible to apply (attach) the plating inhibiting material to the outermost surface of the substrate securely at a low cost.

Alternatively, the plating inhibiting material may be transferred to the outermost surface of the substrate by pad printing.

The plating inhibiting material can be easily transferred to the outermost surface of the substrate also by this method.

In a preferred aspect of the present invention, the plating inhibiting material is attached to the outermost surface of the substrate by screen printing using a screen for screen printing, thereby forming a self-assembled molecular monolayer.

Alternatively, the plating inhibiting material may be attached to the outermost surface of the substrate by pad printing, thereby forming a self-assembled molecular monolayer.

The plating inhibiting material can be securely applied (attached) to the outermost surface of the substrate by this method.

The present invention also provides a plated film forming method for forming a plated metal on a surface of a substrate having a portion coated with a plating inhibiting material and a portion not coated with the material, comprising: applying the plating inhibiting material in an amount corresponding to a desired plated thickness to an outermost surface of the substrate by a method according to any one of claims 1 to 24; carrying out plating to deposit a plated metal on the outermost surface of the substrate including interior surfaces of recesses; and heat-treating the plated metal.

By controlling the amount of the plating inhibiting material per unit area of the outermost surface of the substrate to which the plating inhibiting material is to be applied, it becomes possible to form a film of plated metal (plated film) also in the portion covered with the plating inhibiting material while controlling the film-forming rate. Thus, the plated film can be formed not only on the interior surfaces of fine recesses, such as trenches, but also on the outermost surface of the substrate with no fine recesses formed. By controlling the amount of the plating inhibiting material covering the outermost surface of the substrate as described above and also controlling the plating time and plating conditions, a flat plated film can be formed over the entire substrate.

Since a plated film, such as a copper film, having a large volume as a whole can thus be obtained, post-plating heat treatment can attain the intended effects, such as re-crystallization and a reduction of strain of the plated metal, providing the plated metal with more desirable physical properties for interconnect material. In this connection, in case a plated metal is formed only in fine recesses such as trenches, the stain reduction effect, etc. of heat treatment is small because of the small volume of the plated metal formed. By effecting plating also in the portion covered with a plating inhibiting material, a plated metal integrated with the plated metal in fine recesses, such as trenches, and having a large volume as a whole, can be formed. Accordingly, the stain reduction effect, etc. of heat treatment can be enhanced.

Furthermore, since a thin flat plated film (copper film) can be formed over the entire surface of a substrate upon completion of plating, strain of the plated metal after heat treatment is small. Therefore, a later CMP processing can be carried out in a shorter time without separation between layers. The plating inhibiting material strongly adhering to the surface of the substrate is polished away in the CMP processing and, therefore, does not cause any problem.

The present invention also provides a substrate processing apparatus comprising: a plating tank for holding a plating solution; an anode disposed in the plating solution in the plating tank and opposite a substrate with a plating inhibiting material for inhibiting plating attached to an outermost surface of the substrate surface excluding interior surfaces of recesses; and a plating power source for applying a predetermined plating voltage between the anode and the substrate.

Preferably, the substrate processing apparatus further comprises a polarity switching section for switching the voltage applied between the anode and the substrate so that the polarity is reversed.

The present invention also provides a plating inhibiting material-transferring stamp for use in transferring a plating inhibiting material for inhibiting plating to an outermost surface of a substrate surface excluding interior surfaces of recesses formed in the substrate, when forming interconnects in the substrate by filling the recesses with a plated metal by electroplating, comprising at least a plating inhibiting material-carrying portion of the stamp comprising at least one of a silicone resin and a fluorocarbon resin.

Preferably, the stamp further comprises a support for supporting the plating inhibiting material-carrying portion.

At least an external surface of the plating inhibiting material-carrying portion preferably is a flat plate-like or cylindrical face.

The present invention also provides a plating inhibiting material application apparatus for applying a plating inhibiting material to an outermost surface, which excludes interior surfaces of recesses, of a substrate surface to be plated, comprising: a high-vacuum chamber; a substrate holder, disposed in the high-vacuum chamber, for fixing the substrate; a jet orifice, disposed in the high-vacuum chamber, for jetting the plating inhibiting material; and a vacuum pump for vacuumizing the high-vacuum chamber.

This apparatus can attach a plating inhibiting material only to the outermost surface of a substrate without the need for patterning e.g., with a resist, and thus can simplify the processing. Further, by designing the apparatus to be capable of changing the relative position between the substrate holder and the jet orifice, the angle between the surface of the substrate and the plating inhibiting material jetted in the form of a beam from the jet orifice can be adjusted to an appropriate angle, so that the plating inhibiting material can be attached to the outermost surface of the substrate in a more desirable manner.

The present invention also provides another plating inhibiting material application apparatus for applying a plating inhibiting material to an outermost surface, which excludes interior surfaces of recesses, of a substrate surface to be plated, comprising: a substrate holder for fixing the substrate; a stamp for transferring and attaching the plating inhibiting material carried on the stamp to the outermost surface of the substrate by pressing the stamp against the surface of the substrate; and a press mechanism for pressing the stamp against the surface of the substrate.

This apparatus can securely apply a plating inhibiting material to the outermost surface of a substrate. Furthermore, by providing a pressure control mechanism for controlling the pressure of the stamp on a surface of a substrate at a desired value, the plating inhibiting material can be attached to the outermost surface of the substrate at the optimum pressure for the type of the plating inhibiting material and other processing conditions used, so that application of the plating inhibiting material can be carried out in a more desirable manner.

Preferably, the portion of the stamp which is to be pressed against the surface of the substrate has a flat plate-like shape parallel to the surface of the substrate or a cylindrical shape whose axis is parallel to the surface of the substrate.

Such a stamp can securely apply the plating inhibiting material to the surface of the substrate.

The present invention also provides another plating inhibiting material application apparatus for applying a plating inhibiting material to an outermost surface, which excludes interior surfaces of recesses, of a substrate surface to be plated, comprising: a substrate holder for fixing the substrate; a screen; a screen frame for fixing the peripheral portion of the screen; and a squeegee, a tool for applying a pressure, which is to be moved in a direction parallel to the surface of the substrate while holding the plating inhibiting material between it and the screen and applying a pressure on the screen to press it against the surface of the substrate, so that by the pressure the screen is brought into sequential contact with the surface of the substrate and the plating inhibiting material is allowed to permeate the screen and to be attached to the surface of the substrate; wherein the screen comprises two layers of a layer having a mesh structure and a layer comprising a porous elastic material, and the layer comprising the porous elastic material is disposed on the side to be brought into contact with the surface of the substrate when the pressure is applied by the squeegee.

This apparatus can carry out application of a plating inhibiting material securely at a low cost.

The present invention also provides a metal vapor deposition apparatus for vapor-depositing a metal onto an outermost surface, which excludes interior surfaces of recesses, of a substrate surface, comprising: a high-vacuum chamber; a substrate holder, disposed in the high-vacuum chamber, for fixing the substrate; a vapor deposition source, disposed in the high-vacuum chamber, for melting a metal placed therein and generating vaporized particles of the metal; a heater for heating the metal in the vapor deposition source; and a vacuum pump for vacuumizing the high-vacuum chamber.

This apparatus can vapor-deposit a metal thinly only on an outermost surface of a substrate without deposition of the metal on interior surfaces of recesses, such as trenches, formed in the substrate. Since a plating inhibiting material, such as an SAM-forming molecular species, easily adheres to the metal, a layer of plating inhibiting material, such as a self-assembled molecular monolayer, can be formed firmly. Thus, the object of application of plating inhibiting material can be achieved more securely. Furthermore, by designing the apparatus to be capable of changing the relative position between the substrate holder and the vapor deposition source, the incidence angle of vaporized particles with respect to the surface of the substrate can be adjusted to an appropriate angle, so that the metal can be vapor-deposited onto the outermost surface of the substrate in a more desirable manner.

The present invention also provides another substrate processing apparatus comprising: a liquid application section for applying a liquid containing a dissolved plating inhibiting material to an outermost surface, which excludes interior surfaces of recesses, of a substrate surface; a drying section for drying the liquid which has been applied to the substrate in the liquid application section; and a plating section for carrying out plating of the substrate which has been dried-in the drying section.

According to this apparatus, by first applying a liquid containing a dissolved plating inhibiting material to a predetermined surface region (outermost surface) of a substrate in the liquid application section and drying the liquid in the drying section, and then carrying out plating of the substrate, a plated metal can be quickly filled into recesses, such as trenches and contact holes, formed in the surface of the substrate while avoiding the formation of voids in the embedded metal.

The substrate processing apparatus may further comprise a wet processing section comprised of at least one of a CMP apparatus, an electrolytic etching apparatus, an electrolytic polishing apparatus, a chemical etching apparatus and a cleaning apparatus.

In a preferred aspect of the present invention, the liquid application section applies the liquid to a surface of the substrate, the substrate surface excluding the bottom surfaces and those portions of the side surfaces which lie in the vicinity of the bottom surfaces of trenches and/or holes, having a trench width or hole diameter of 0.01 to 200 μm, provided in the surface of the substrate.

This makes it possible to inhibit deposition of a plated film on interior surfaces of trenches and/or holes (especially interior surfaces at openings) other than the bottom surfaces and those portions of the side surfaces which lie in the vicinity of the bottom surfaces, and to effectively fill even such fine recesses with a plated metal without the formation of voids in the embedded metal.

In a preferred aspect of the present invention, the liquid application section includes at least one of a movement mechanism for bringing a flat or cylindrical stamp for application of the liquid into contact with the substrate and moving the stamp horizontally or vertically with respect to the substrate, a mechanism for bringing a flat stamp into contact with the substrate and rotating the stamp, a rotating mechanism for bringing a cylindrical stamp into contact with the substrate and rotating the stamp, and a spray mechanism for spraying the liquid onto the surface of the substrate.

This enables effective application of the liquid containing a dissolved plating inhibiting material to a predetermined region of an outermost surface of a substrate.

In a preferred aspect of the present invention, the liquid application section includes a substrate holder comprising a chucking mechanism for chucking a peripheral portion of the substrate or an attraction mechanism for attaching the non-processing surface of the substrate, and a movement mechanism for horizontally moving, vertically moving or rotating the substrate held by the substrate holder.

This makes it possible to effectively apply the liquid containing a dissolved plating inhibiting material to a predetermined region of the surface of the substrate while horizontally moving, vertically moving or rotating the substrate held by the substrate holding mechanism.

In a preferred aspect of the present invention, the drying section comprises at least one of a heating section for heating the substrate, an air-blowing section for blowing air onto the substrate, and a rotating section for rotating the substrate.

This enables effective drying of the liquid containing a dissolved plating inhibiting material applied to a predetermined region of the surface of the substrate.

In a preferred aspect of the present invention, the liquid application section and the drying section are spatially isolated from a wet-processing section including the plating section.

This can eliminate the influence of a wet-processing section on the liquid application section and the drying section.

The present invention also provides another substrate processing method comprising: applying a liquid containing a dissolved plating inhibiting material to an outermost surface, which excludes interior surfaces of recesses, of a substrate surface; drying the liquid applied to the substrate; and carrying out plating of the surface of the substrate after drying.

This method can quickly fill recesses, formed in a substrate, with a plated metal while avoiding the formation of voids in the embedded metal.

### BRIEF DESCRIPTION OF THE DRAWINGS

FIGS. 1A through 1C are diagrams illustrating, in a sequence of process steps, a conventional damascene process for the formation of substrate interconnects;

FIG. 2 is a layout plan view of a conventional substrate processing apparatus for carrying out electroplating;

FIGS. 3A through 3D are diagrams illustrating, in a sequence of process steps, a conventional damascene process for the formation of substrate interconnects;

FIGS. 4A and 4B are diagrams illustrating the state of a substrate in the course of a conventional damascene process for the formation of substrate interconnects;

FIG. 5 is a diagram illustrating the state of a substrate in one step of a conventional damascene process for the formation of substrate interconnects;

FIG. 6 is a diagram illustrating the state of a substrate in one step of a conventional damascene process for the formation of substrate interconnects;

FIG. 7 is a conceptual diagram schematically showing the construction of the main portion of an apparatus for carrying out a pre-processing of a substrate according to the present invention;

FIG. 8 is an enlarged view of the portion A of FIG. 7;

FIG. 9 is a conceptual diagram schematically showing the construction of the main portion of a plating inhibiting material application apparatus according to the present invention;

FIG. 10 is a conceptual diagram schematically showing the construction of the main portion of a plating inhibiting material application apparatus (micro-contact printing apparatus) according to the present invention;

FIG. 11 is a conceptual diagram schematically showing the construction of a stamp of the plating inhibiting material application apparatus according to the present invention;

FIG. 12 is a conceptual diagram illustrating transfer of an ink to a substrate by the plating inhibiting material application apparatus according to the present invention;

FIG. 13 is a conceptual diagram illustrating transfer of an ink to a substrate by another plating inhibiting material application apparatus according to the present invention;

FIGS. 14A and 14B are conceptual diagrams showing the construction of an ink application screen of a plating inhibiting material application apparatus (screen printing) according to the present invention, FIG. 14A showing a plan view and FIG. 14B showing a cross-sectional view;

FIG. 15 is a conceptual diagram illustrating transfer of an ink to a substrate by the plating inhibiting material application apparatus (screen printing) according to the plating invention;

FIG. 16 is a diagram showing the construction of a substrate processing apparatus according to the present invention;

FIGS. 17A through 17D are diagrams illustrating, in a sequence of process steps, a process for the formation of substrate interconnects according to the present invention;

FIG. 18 is a layout plan view of a substrate processing apparatus for carrying out electroplating according to the present invention.

FIG. 19 is a diagram schematically showing the construction of a liquid application section of a liquid application/drying section, of a substrate processing apparatus of the present invention;

FIG. 20 is a diagram schematically showing the construction of a drying section of the liquid application/drying section of the substrate processing apparatus of the present invention;

FIGS. 21A through 21D are diagrams illustrating, in a sequence of process steps, a damascene process according to a substrate processing method of the present invention;

FIG. 22 is a diagram illustrating a substrate surface when recesses are filled with a plated metal in a damascene process according to the substrate processing method of the present invention; and

FIG. 23 is a layout plan view of a substrate processing apparatus for carrying out electroplating according to the present invention.

### DETAILED DESCRIPTION OF THE PREFERRED EMBODIMENTS

Preferred embodiments of the present invention will now be described. A substrate processing method according to the present invention includes, as a step before the so-called damascene plating involving filling recesses such as trenches and contact holes, formed in a substrate, with a plated metal such as copper by electroplating, a plating inhibiting material attachment step of attaching, e.g., by means of transfer, an ink (plating inhibiting material), a plating inhibitor, selectively to the outermost surface of the substrate (generally the outermost surface of a barrier layer covering an insulating film or of a seed layer overlying the barrier layer), i.e., the substrate surface excluding the interior surfaces of the recesses, thereby controlling the thickness of a copper film which is to be removed in a post-damascene plating step. The term “ink” herein refers to a material to be finally attached to the outermost surface of e.g., a barrier layer of a substrate. An ink, generally in the form a solution of the ink as a solute in an appropriate solvent, is applied to a plating inhibiting material-carrying portion of a stamp and then attached (transferred) to an outermost surface of a substrate.

The ink attachment step is a pre-damascene plating step of attaching an ink selectively onto an extra seed layer or barrier layer, other than that of interconnect portions of a semiconductor device, to be removed in a post-damascene plating step, and is carried out to inhibit the growth of a plated film in damascene plating, which is an electroplating.

The present electroplating process includes a step of attaching a plating inhibiting material to the outermost surface of a substrate, i.e., the substrate surface in which recesses, such as trenches and contact holes for embedding a metal therein, are formed and from which the interior surfaces, such as the wall surfaces and the bottom surfaces, of the recesses are excluded, and a later step of carrying out electroplating of the substrate.

After the step of attaching a plating inhibiting material to an outermost surface of a substrate and the step of carrying out electroplating of the substrate, it is preferable to carry out a step of releasing the plating inhibiting material from the outermost surface of the substrate by a reverse-electrolysis processing with reverse polarity to that of the electroplating. It is more preferable to again carry out electroplating processing as an additional step after the above steps.

Besides the reverse-electrolysis processing with reverse polarity to that of the electroplating, the following methods (A) to (D) can be used to release the plating inhibiting material from the outermost surface of the substrate:

(A) A method of releasing the plating inhibiting material from the outermost surface of the substrate in or outside a plating solution by an elastic body having such physical properties as not to damage the substrate.

(B) A method of releasing the plating inhibiting material from the outermost surface of the substrate outside a plating solution by immersing the substrate in a solution which dissolves the plating inhibiting material.

(C) A method of releasing the plating inhibiting material from the outermost surface of the substrate in or outside a plating solution by ultrasonically vibrating the surface of the substrate.

(D) A method of releasing the plating inhibiting material from the outermost surface of the substrate in or outside a plating solution by applying a water pressure to the surface of the substrate by a nozzle or the like.

When the attachment of plating inhibiting material is carried out by means of transfer, a stamp and an ink dissolved in a solvent are used. The transfer process comprises first preparing a stamp and applying an ink dissolved in a solvent to the stamp, and then bringing the ink-applied face of the stamp into contact with the ink-receiving surface of the substrate, thereby transferring the ink to the outermost surface of the substrate.

A description will now be made of a pre-processing step (deposition of a metal or the like on a surface), which is optimally carried out before plating inhibiting material application, and a step of applying a plating inhibiting material, such as an SAM-forming molecular species, onto the substrate.

[Pre-Processing Before Plating Inhibiting Material Application]

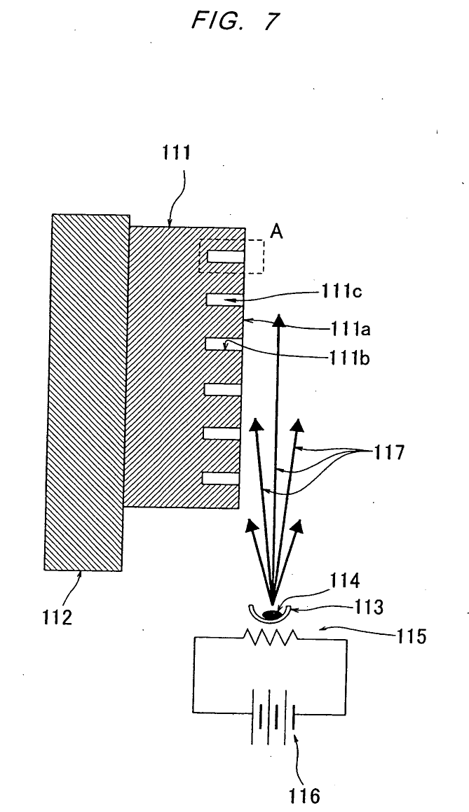

First, a pre-processing step before plating inhibiting material application will be described. FIG. 7 shows the internal structure of an apparatus for carrying out pre-processing of a substrate. As shown in FIG. 7, the apparatus includes a substrate holder 112 for fixing a substrate 111 with its front surface (the surface with recesses 111c such as trenches formed therein) held vertically, and a vapor deposition source 113 disposed below the substrate holder 112. A predetermined metal 114 is placed in the vapor deposition source 113. The metal 114 is heated by a heating source, such as a heater 115, to which a heating current is supplied from a power source 116, thereby melting the metal 114 and vaporizing it as vaporized particles 117 from the vapor deposition source 113.

The vapor deposition source 113 is disposed below the outermost surface 111a of the substrate 111, i.e., the substrate surface excluding the interior surfaces 111b of the surface recesses 111c, lying approximately on a line extending from the outermost surface 111a, and at a predetermined distance from the substrate 111. The vapor deposition source 113, the substrate 112, etc. are disposed in a not-shown vacuum chamber, which is connected to a not-shown vacuum pump for high vacuum-evacuation, so that the vacuum chamber can be highly vacuum-evacuated.

The operation of the apparatus will now be described. First, the substrate 111 as a workpiece is fixed to the substrate holder 112 with the outermost surface 111a on the far side from the substrate holder 112. Next, the vacuum pump is actuated to evacuate the vacuum chamber housing the substrate 111, etc. until the vacuum in the vacuum chamber reaches such a high vacuum that the mean free path of the remaining gas becomes at least equal to the distance from the vapor deposition source 113 to the upper end of the substrate 111. The predetermined metal 114 in a predetermined amount has been placed in the vapor deposition source 113. Au, to which an SAM-forming molecular species easily adheres, is preferably used as the predetermined metal 114. A seed layer or a barrier layer is formed on the surface of the substrate 111, and the adhesion between the seed layer or the barrier layer and an SAM-forming molecular species is weak as compared to the adhesion between Au and the SAM-forming molecular species. It is therefore preferred to form an Au film in a region for which the formation of SAM is intended.

The vapor deposition source 113 is heated by the heater 115 or the like to melt the metal 114 and vaporize it as vaporized particles 117 from the vapor deposition source 113. Since the vaporized particles 117 fly in high vacuum as described above, they move straight without colliding with other remaining gas molecules until their flight reaches approximately the distance to the upper end of the substrate 111. The vaporized particles 117 fly generally radially from the vapor deposition source 113. Accordingly, by appropriately adjusting the horizontal relative position between the substrate 111 and the vapor deposition source 113, the vaporized particles 117 can be made to fall on the outermost surface 111a of the substrate 111 at a desired incidence angle. Thus, by appropriately adjusting the horizontal relative position between the substrate 111 and the vapor deposition source 113, the vaporized particles 117 can be made to fall on the outermost surface 111a approximately parallel thereto.

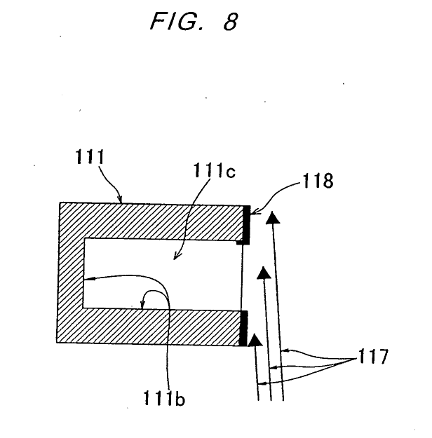

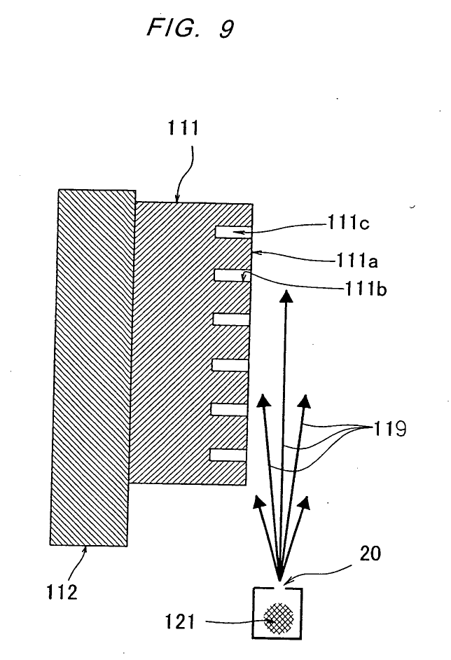

Further, by making the distance between the substrate 111 and the vapor deposition source 113 not less than a certain length, the incidence angle of the vaporized particles 117 at the upper end of the substrate 111 can be made substantially (or virtually) equal to the incidence angle at the lower end of the substrate 111. Thus, as shown in FIG. 8, the vaporized particles 117 fly approximately parallel to the surface of the substrate 111, and fall on and adhere to the outermost surface 111a of the substrate 111, while the vaporized particles 117 seldom or never enter the recesses 111c such as fine trenches. Thus, virtually, the vaporized particles 117 can be attached only to the outermost surface 111a of the substrate 111, i.e., the substrate surface excluding the interior surfaces 111b of the recesses 111c such as fine trenches, to form a vapor-deposited film 118. FIG. 8 is an enlarged view of the portion A of FIG. 7.

The apparatus shown in FIG. 7 is an exemplary apparatus. Other apparatuses can also achieve the above object insofar as they are so constructed as to allow vaporized particles to fall on the surface of a substrate approximately parallel thereto.

The amount of the vaporized particles 117 to be attached to the outermost surface 111a of the substrate 111 can be controlled by appropriately selecting the temperature of the vapor deposition source 113, the vapor deposition time, and the like. Control of the vapor deposition time can be facilitated by providing a not-shown shutter between the vapor deposition source 113 and the substrate 111. Thus, the vapor deposition time can be controlled by opening the shutter for a predetermined time. Further, by providing a not-shown film-thickness sensor in the vicinity of the substrate 111, the thickness of the vapor-deposited film 118 can be monitored in real-time, thereby controlling the amount of the vapor-deposited vaporized particles 117.

The vacuum chamber is preferably provided with a not-shown load lock chamber. The provision of a load lock chamber makes it possible to carry the substrate 111 into and out of the vacuum chamber while keeping the interior of the vacuum chamber at a high vacuum, thus shortening the processing time.

The substrate holder 112 is preferably provided with a rotating mechanism for the substrate 111 so that the substrate 111 can be rotated. This makes it possible to make the thickness of the vapor-deposited film 118 uniform over the entire outermost surface 111a of the substrate 111.

The adjustment of the incidence angle of vaporized particles can be facilitated by designing the substrate holder 112 to be movable vertically to the substrate-fixing face.

While a method for the formation of vapor-deposited film (metal layer) 118 on the outermost surface 111a of the substrate 111 as a pre-processing before plating inhibiting material application (attachment) has been described, a metal film may also be formed by vapor deposition using a mask, CVD, sputtering, or the like, or by micro-contact printing.

The above description has been made on the premise of the formation of SAM on the outermost surface 111a of the substrate 111 in the subsequent step. However, the object of the formation of SAM on the outermost surface 111a of the substrate 111 resides in inhibiting deposition of e.g., copper onto the outermost surface 111a of the substrate 111 during copper electroplating by utilizing the electrical insulating properties of SAM. Therefore, in case an insulating film can be directly formed, for example by the above-described vapor deposition method, on the outermost surface 111a of the substrate 111, the insulating film may be directly formed on the outermost surface 111a of the substrate 111. In this case, the step of SAM formation can be omitted.

The pre-processing for facilitating attachment of a plating inhibiting material, such as an SAM-forming molecular species, to the outermost surface of a substrate is thus completed.

Though the above-described apparatus is a metal vapor deposition apparatus, the apparatus can be modified to construct a plating inhibiting material application apparatus by disposing a small nozzle 120 as a plating inhibiting material jet orifice at a position corresponding to the position of the vapor deposition source of the metal vapor deposition apparatus, so that an ink 121 (e.g., the below-described SAM-forming molecular species-containing ink) is jetted from the small nozzle 120, with the other construction substantially the same. Thus, for example, the vapor deposition source 113, the heater 115, the power source 116, etc. for use in the metal vapor deposition apparatus can be replaced with the small nozzle 120, etc. for use in a plating inhibiting material application apparatus. The term “ink” primarily means a solution of a plating inhibiting material, which adheres to the outermost surface of a substrate before plating and inhibits plating, dissolved as a solute in an appropriate solvent.

For example, a solution containing an SAM-forming molecular species dissolved as a solute in an appropriate solvent (an alcohol such as methanol or ethanol, acetone, or the like) can be preferably used as an ink. The term “ink” can secondarily mean a solute itself of an ink. For example, when an ink of a plating inhibiting material in a solvent is applied to a surface of a substrate and the solvent is evaporated, the remaining solute fixed to the substrate can also be referred to as an ink. Some plating inhibiting material (ink) forms a plating inhibiting film and, in this case, the plating inhibiting material (ink) can refer to the solution and also to the solute.

In the case where a solute (e.g., SAM-forming molecular species) itself is liquid, it can be used as it is as an ink 121 without a solvent. Usually, however, an ink containing a solute dissolved in a solvent or an ink containing a solute whose concentration is adjusted with a solvent, is used. An appropriate solvent may be selected for a particular solute in consideration of solubility parameters, miscibility, etc. to dissolve the solute and adjust its concentration.

Also in the case of the plating inhibiting material application apparatus in which the ink 121 is jetted from the small nozzle 120, provided the vacuum chamber is kept at a sufficiently high vacuum, the ink 121 jetted from the small nozzle 120 flies as a beam-like ink 119 in high vacuum and falls on the outermost surface 111a of the substrate 111, whereby a plating inhibiting material (e.g., solution of an SAM-forming molecular species) is attached to the outermost surface 111a of the substrate 111. A layer of plating inhibiting material (e.g., SAM) can thus be formed by this method. This method can omit the below-described step of forming a plating inhibiting material layer (e.g., SAM) e.g., by a stamp. As with the above-described vapor deposition apparatus, it is preferred to provide this apparatus with a rotating mechanism or a linear movement mechanism for the substrate 111 and also a movement mechanism for moving the substrate holder 112 vertically to its substrate-fixing face, because the ink 121 (e.g., a solution of an SAM-forming molecular species) can be supplied uniformly to the entire outermost surface 111a of the substrate 111.

[Apparatus and Method for the Formation of Plating Inhibiting Material Layer]

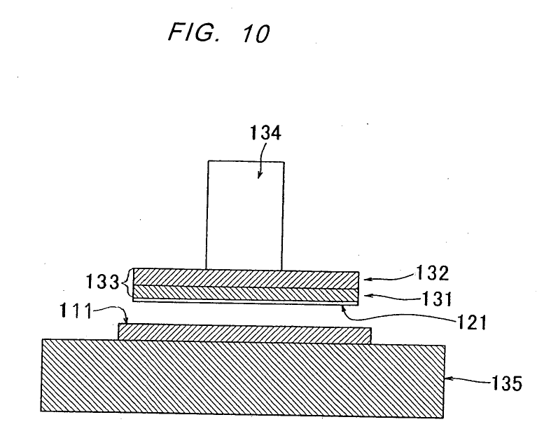

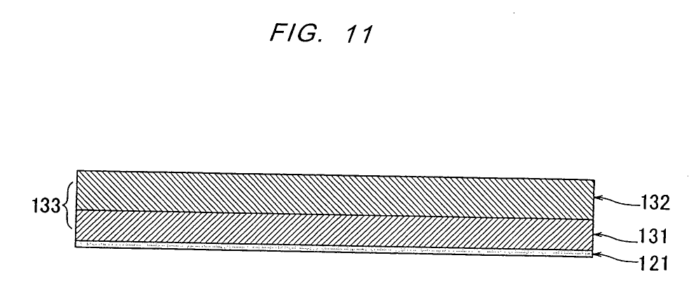

A description will now be made of an apparatus and method for the step of applying a plating inhibiting material (ink), such as an SAM-forming molecular species, to the outermost surface of a substrate to form a plating inhibiting film. FIG. 10 shows a conceptual diagram of an apparatus for forming SAM. This apparatus mainly comprises a stamp 133 composed of a plating inhibiting material-carrying portion 131 and a support 132, a press mechanism 134, and a substrate holder 135. An SAM can be formed on the outermost surface 111a of the substrate 111 basically by applying an ink 121, containing an SAM-forming molecular species for forming SAM, to the plating inhibiting material-carrying portion 131 of the stamp 133, and transferring the ink 121 to the outermost surface 111a of the substrate 111.

FIG. 11 shows a conceptual diagram of the stamp 133, the main component for SAM formation. The stamp 133 is composed of a support 132 and a plating inhibiting material-carrying portion 131 comprising an elastic material. A silicon resin is preferably used as the elastic material for the plating inhibiting material-carrying portion 131. Examples of usable silicone resins include polydimethylsiloxane (PDMS), PDMS/methyl-H-Siloxane copolymer and H-terminal polydimethylsiloxane. These silicone resins are commonly used in the existing micro-contact printing technology. Silicone resins, unlike common rubbers having carbon-backbone C—C bonds, have Si—O bonds in the main chain. Rubber shaving such Si—O bonds have better releasability to the ink 121 or the like. Thus, when a silicone resin is used for the plating inhibiting material-carrying portion 131, the ink 121 detaches more easily from the plating inhibiting material-carrying section 131 upon transferring the ink 121 to the outermost surface 111a of the substrate 111, which is desirable for the plating inhibiting material-carrying portion 131.

Materials other than silicone resins can be used as the elastic material for the plating inhibiting material-carrying portion 131, provided that the materials can provide a high surface flatness. For example, resins other than silicone resins, metals, and inorganic compounds such as glass and ceramics may be used. It is desirable that the plating inhibiting material-carrying portion 131 have such a high flatness that the surface roughness is smaller than the surface roughness or undulation of an ink-receiving substrate. Further, it is desirable to use such a material that the plating inhibiting material-carrying portion 131 does not swell and lower the flatness when the ink 121 is applied thereto.

In the case where the ink 121 is transferred to a non-flat surface, such as a surface of a semiconductor wafer having recesses 111c, such as trenches, for which ink application is not intended, the plating inhibiting material-carrying portion 131 desirably is not so soft that it can intrude into the recesses 111c. However, in case the plating inhibiting material is intended to be transferred to upper portions of the interior surfaces of the fine recesses 111c such as trenches, in particular those portions of the interior surfaces 111b of the recesses 111c which lie in the vicinity of the outermost surface 111a of the substrate 111, the plating inhibiting material-carrying portion 131 preferably is relatively soft or has a relatively low hardness.

In the case where the elastic material for the plating inhibiting material-carrying portion 131 is a non-conductive material, it is possible to mix a conductive material or a magnetic material into the elastic non-conductive material so as to control the ink transfer process by means of electric or magnetic field. Examples of the conductive material include metal materials such as metal particles, metal fibers and metal flakes, carbon materials such as carbon nanotubes, carbon wires, carbon coils and carbon particles, and organic conductive materials. In the case of non-conductive plating inhibiting material-carrying portion 131, it is also possible to rather utilize the non-conductivity and electrostatically control the ink transfer process. Thus, the amount of the ink applied and the releasability of the ink can be controlled by intentionally charging the elastic non-conductive material.

A material for the plating inhibiting material-carrying portion 131, for example PDMS, is injected in a liquid state into a mold (corresponding to a casting mold if the plating inhibiting material-carrying portion is likened to a casting) with a face having such a high flatness (generally a mirror face) that its roughness is smaller than the surface roughness or undulation of a substrate, i.e., the surface roughness of a copper seed layer or a barrier layer. Next, the material for the plating inhibiting material-carrying portion 131 is cured at room temperature or a higher temperature, optionally using a curing agent, and the cured product is released from the mold, thereby producing a plating inhibiting material-carrying portion 131 having a mirror-like surface.

After curing the material, such as a silicone resin, for the plating inhibiting material-carrying portion 131, the surface of the plating inhibiting material-carrying portion 131 may be finished into a mirror surface by polishing or the like. In case the plating inhibiting material-carrying portion 131 is weak and its mechanical strength is insufficient for the ink transfer operation, it is preferred to provide a reinforcing support 132 which underlies the plating inhibiting material-carrying portion 131. The support 132 can be provided by a method comprising applying a primer to the support 132, bringing the support 132 into contact with the liquid material for the plating inhibiting material-carrying portion 131, and then curing the material for the plating inhibiting material-carrying portion 131. This method can firmly attach the support 132 to the material, such as a silicone resin, for the plating inhibiting material-carrying portion 131, providing a preferable stamp 333.

The support 132 is a rigid body that supports the plating inhibiting material-carrying portion 131 comprising the above-described elastic material. Because of the rigidity, the support 132 can transmit the pressure from the press mechanism 134 uniformly to the plating inhibiting material-carrying portion 131. The plating inhibiting material-carrying portion 131 of the stamp 133 generally comprises the elastic material (or a metal, glass, ceramic, etc. having a high surface flatness) and a supporting material. In case the elastic material is such a material as a metal, which itself has a fairly high mechanical strength, however, part or the whole of the elastic material may also serve as a supporting material.

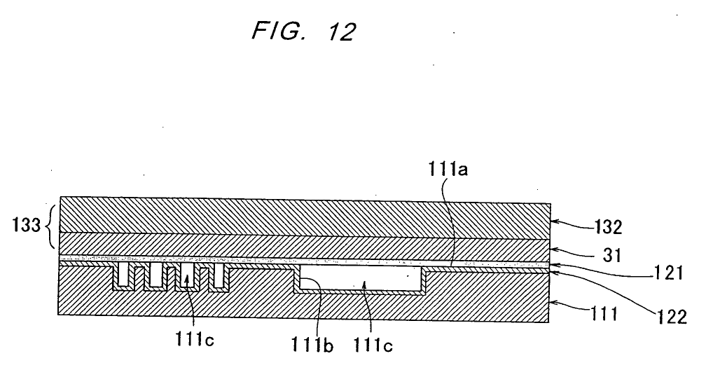

The press mechanism 134 is connected to the support 132 of the stamp 133. By applying a pressure to the stamp 133 by the press mechanism 134, the plating inhibiting material-carrying portion 131 of the stamp 133 can be brought into tight contact with the substrate 111, as shown in FIG. 12, so that the ink 121 for SAM formation can be transferred to the outermost surface 111a of the substrate 111. In this embodiment, the outermost surface 111a of the substrate 111 is the surface of a barrier layer 122. The press mechanism 134 is provided with a pressure gauge and a pressure adjustment mechanism, both not shown, so that the stamp 133 can be pressed against the substrate 111 at the optimum pressure for transfer of the ink 121.

The substrate holder 135 is a component for placing the substrate 111 thereon. The substrate holder 135 is preferably provided with a not-shown mechanism, such as a vacuum chuck or an electrostatic chuck, which can fix the substrate 111. The substrate holder is provided with a not-shown mechanism, which can adjust the position of the substrate holder 135, so that when the stamp 133 is pressed against the substrate 111, the plating inhibiting material-carrying portion 131 of the stamp 133 can be pressed against the entire substrate 111. It is preferable to provide a mechanism which can automatically move the substrate 111 to an optimal location with a sensor for automatically detecting the location of the substrate 111.

The method and apparatus for applying (i.e., attaching) the plating inhibiting material (ink) 121 to the outermost surface 111a of the substrate 111 using the stamp 133, the press mechanism 134, and the like has been described by referring to FIGS. 10 through 12. While an SAM-forming molecular species has been described as a preferable example of the plating inhibiting material, the plating inhibiting material is not limited to this particular material.

Methods for attaching the ink 121 to the outermost surface 111a of the substrate 111 include adsorption (chemical adsorption, physical adsorption, etc.), chemical bonding, anchor effect utilizing surface irregularities, fusion bonding, electrostatic adsorption, etc. The ink 121, because of the need to form a film having a plating inhibiting function, should have a proper degree of adhesion to a seed layer or a barrier layer. The degree of adhesion must be such that the ink 121 is completely removed in a later step of applying an electric field in the reverse direction to the direction of electric field in electroplating. The thickness of the ink 121 received on the ink-receiving seed layer or barrier layer is preferably such that the aspect ratio of trenches or the like in interconnect portions becomes twice at most. That is, the thickness of the ink 121 is preferably at most equal to the depth of trenches or the like (the distance from the outermost surface of the substrate to the bottoms of the trenches or the like) before transfer of the ink 121. Such thickness is generally about 10 Å to 1 μm In the case of attaching the ink 121 to the ink-receiving seed layer or barrier layer by adsorption or chemical bonding, the adhesion of the ink to the seed layer or barrier layer can be evaluated by the HSAM (Hard and Soft Acids Bases) rule that determines the stability of bond between a metal or a cation, an electron-accepting acid, and an anion or a molecule, an electron-donating base. Therefore, an appropriate material can be selected for the ink 121.

When the material of a seed layer or the barrier layer 122, the outermost layer of the substrate 111, is copper, a copper alloy, titanium, a titanium alloy, tantalum, a tantalum alloy, ruthenium, or a ruthenium-alloy, materials having the following structures at the terminal end(s) of the molecule can be suitably used for the ink: RSH, R2S, RS⁻, I⁻, SCN⁻, S₂O₃²⁻, R₃P, R₃As, (RO)₃P, CN⁻, RCN⁻, CO, C₂H₄, C₆H₆, etc. (R is an alkali or aryl group).

Examples of such materials include alkanethiol, benzotriazole, casein, dextrin, dimethylamino derivatives, 1,8-disulfonic acid, ethylene oxide, gelatin, glue, lactose benzoil hydrazone, molasses, petroleum sulfonic acid, o-phenanthroline, polyethoxy ether (polyethylene glycol), polyethylene imine, poly N,N′-diethyl safranine, polypropylene ether, propylene oxide, sugar, thiourea, polyalkylene glycol, animal glue, polymers containing an ether group, high-protein polymers of amino acid, polyethylene oxide, hydroquinone or ethoxylated alkylphenol, glycol, amine, alkoxylated lactam amide, disubstituted ethane sulfonic acid, urea and glycerin, urea, sodium lauryl sulfonate, tosyl or mesyl sulfonic acid, phenazine dye, polyether surfactant+benzenesulfonic acid+grain improver, polyether+mercaptoimidazole+benzenesulfonic acid, polyether+organic divalent sulfur compound+tertiary alkylamine+polyepichlorohydrin, sulfamic acid, alkylated polyalkylene imine, ω-sulfo-n-propyl-N,N-diethyldithiocarbamate+polyethylene glycol+crystal violet, phthalocyanine+tertiary alkylamine+polyepichlorohydrin+benzenesulfonic acid, phenolphthalein, a substituted phthalocyanine radical, regular coffee, disulfide, sulfonic acid, aliphatic aldehyde, di or triaminotriphenylmethane dye and sulfoalkyl sulfide, polyether, polysulfide, heterocyclic sulfur and polyether compound, formaldehyde and thio urea, an ethylene oxide product and 2-mercaptopyridine, thiourea and polyether, polyethers, polymericphenazonium compounds, tannin (acid), and various complexing agents that make a coordinate bond with copper.

Though some of the above materials can be used as they are as the ink 121 in case they are liquid, the materials in a solid or liquid state are generally used as a solute dissolved in a solvent. An appropriate solvent can be selected for a particular material in consideration of solubility parameters and miscibility to dissolve the material and adjust its concentration.

In the case where the material of the ink-receiving surface, i.e., the material of the outermost seed layer or barrier layer 122 of the substrate 111, is copper, a copper alloy, titanium, a titanium alloy, tantalum, a tantalum alloy, ruthenium or a ruthenium alloy, and the ink 121 is attached to the substrate 111 by anchor effect, polymeric compounds, such as known photoresists, can be used for the ink 121.

Similarly, in the case of ink transfer by fusion bonding, low-melting metals can be used for the ink 121 and its solvent.

In the case of ink transfer by electrostatic adsorption, it is possible to use a solution containing a solvent and fine particles which function as the ink 121 and have a different complex dielectric constant from that of the solvent. With the solvent of the solution not evaporated, a direct-current or alternating-current voltage is applied between the plating inhibiting material-carrying portion 131 of the stamp 133 and the outermost surface (barrier layer 122) 111a of the substrate 111, shown in FIG. 12, to cause electrophoresis or dielectrophoresis, thereby fixing the fine particles as the ink 121 on the outermost surface 111a of the substrate 111. Particles of a metal oxide or a nonmetal oxide or particles of a polymeric compound can be used as the fine particles.

[Method for Forming a Plating Inhibiting Film on the Outermost Surface of a Substrate]

A method for forming a plating inhibiting film (plating inhibiting material layer), for example SAM, on the outermost surface 111a of the substrate 111 by using the above-described apparatus with now be described. First, the ink 121 containing an SAM-forming molecular species for SAM formation is applied to the surface of the plating inhibiting material-carrying portion 131, comprising an elastic material, of the stamp 133. The application of the ink 121 may be carried out by pressing the plating inhibiting material-carrying portion 131 of the stamp 133 on an inkpad impregnated with the ink 121, or by spraying the ink 121 onto the surface of the elastic material which constitutes the plating inhibiting material-carrying portion 131.

The ink 121 can also be applied to the plating inhibiting material-carrying portion 131 by using a normal-rotation roll coater, a reverse roll coater, a gravure coater, a knife coater, a blade coater, a rod coater, an air doctor coater, a curtain coater, a fountain coater, a kiss coater, a dip coater, a screen printing machine, a spin coater, a cast coater, a spray coater, an impregnating machine, an extrusion coater, a vacuum coater, a coater using an LB method, etc. The stamp 133 carrying the ink 121 on the surface of the plating inhibiting material-carrying portion 131 can thus be prepared, as shown in FIG. 11.

Next, the plating inhibiting material-carrying portion 131 comprising an elastic material, carrying the ink 121, is pressed against the surface (the surface of the barrier layer 122) of the substrate 111, as shown in FIG. 12. When a pressure is applied by the press mechanism 134 on the support 132, the pressure is transmitted to the plating inhibiting material-carrying portion 131, comprising an elastic material, coupled to the support 132, whereby the plating inhibiting material-carrying portion 131 is pressed against the substrate 111 and the ink 121 on the plating inhibiting material-carrying portion 131 is transferred to the outermost surface 111a of the substrate 111. As shown in FIG. 12, upon the ink transfer, the plating inhibiting material-carrying portion 131, comprising an elastic material, contacts only the outermost surface 111a of the substrate 111 and does not contact the interior surfaces 111b of the recesses 111c such as fine trenches. Accordingly, the ink 121 is transferred only to the outermost surface 111a (i.e., the outermost surface of the barrier layer 122, the outermost layer of the substrate 111), and is not transferred to the interior surfaces 111b of the recesses 111c such as fine trenches.

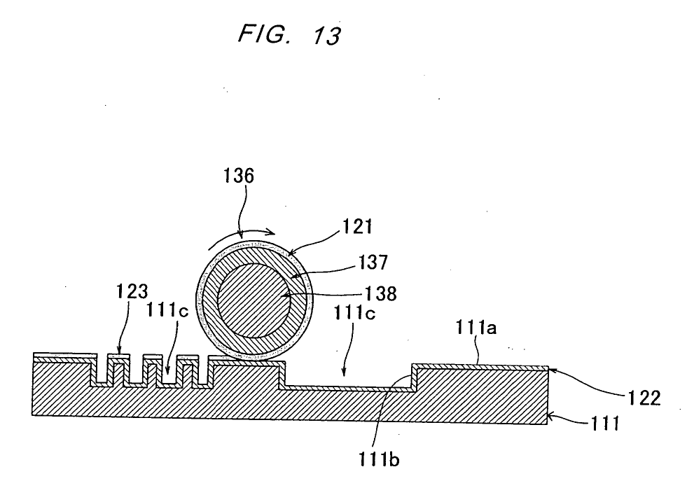

While ink transfer using the flat plate-shaped stamp 133 has been described, a stamp of other shape, for example, a roller-shaped or cylindrical stamp shown in FIG. 13, may also be used. The support 138 of the roller-shaped stamp 136 has a shape corresponding to the core of the roller, and a press mechanism is mounted to the rotating shaft of the roller. As with the above-described case, the ink 121 may be applied to the plating inhibiting material-carrying portion 137 comprising an elastic material by using an inkpad or by spraying. It is also possible to provide an ink 121 supply device above the roller-shaped stamp 136 so that the ink 121 can be continually supplied to the surface of the plating inhibiting material-carrying portion 137 comprising an elastic material. With this structure, it is possible to use a smaller-sized stamp 136 and to form an SAM on a large-area substrate 111.

It is also possible to make the plating inhibiting material-carrying portion 137 a porous body, continually supply the ink 121 to the support 138, and allow the ink 121 supplied to the support 138 to seep into the porous body. This method also can continually supply the ink 121 to the plating inhibiting material-carrying portion 137, making it possible to easily transfer the ink 121 from the plating inhibiting material-carrying portion 137 to a large-area substrate 111 and form a plating inhibiting material layer 123 (e.g., SAM) on the outermost surface 111a of the substrate 111.

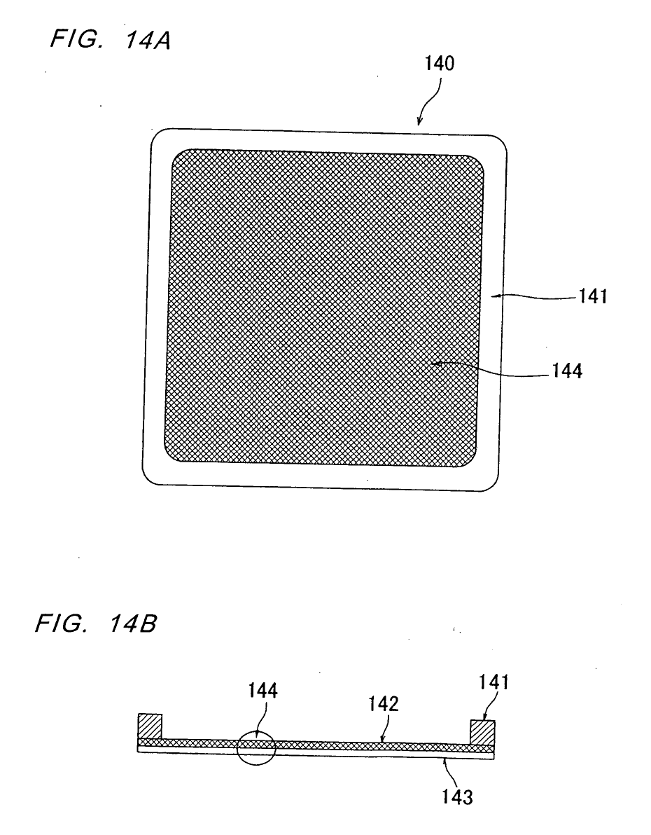

Instead of the use of the stamp 133 or 136, screen printing may be used to apply the ink 121 to the outermost surface 111a of the substrate 111. FIG. 14 shows a schematic view of a screen for use in screen printing. The screen 140 is comprised of a generally-square metal frame 141 and a film 144, set in the metal frame 141, having a two-layer structure of a stainless-steel mesh 142 and a porous elastic material 143. The porous elastic material 143 has such pores as to allow an ink, e.g., containing an SAM-forming molecular species, to seep therethrough.

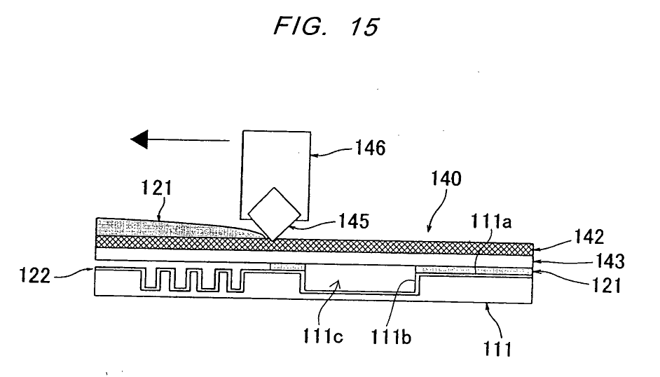

FIG. 15 is a schematic diagram illustrating the formation of SAM by screen printing. As shown in FIG. 15, a squeegee 145 is fixed to a squeegee holder 146 of a screen printing machine, and a load is applied from above on the squeegee 145 so that the squeegee 145 presses the screen 140, comprising the mesh 142 and the porous elastic material 143, downwardly toward the substrate 111 and brings the film 144 of the screen 140 into contact with the substrate 111. The ink 121, which has seeped onto the surface (in contact with the substrate 111) of the porous elastic material 143, is transferred to the outermost surface 111a of the substrate 111. By moving the squeegee 145 while applying the load on it, the ink 121 can be transferred to a wide area. The squeegee 145, which is a component of the screen printing machine, is to be moved in a direction parallel to the outermost surface 111a of the substrate 111 with its front end kept pressed on the surface of the screen 140, thereby allowing the ink 121 to permeate the film 144 of the screen 140 and adhere to the ink-receiving surface.

This method can employ a commercialized widely-used screen printing machine and thus involves no need to develop a new device for SAM formation, and therefore is economical. By adjusting the printing conditions, such as the viscosity of the ink 121, the load applied by the squeegee 145 on the film 144 of the screen 140, the tension of the screen 140, the moving velocity of the squeegee 145, etc., a plating inhibiting film, such as SAM, can be formed on the outermost surface 111a of the substrate 111.

It is also possible to use pad printing instead of screen printing. Since a stamp material for pad printing is generally soft, pad printing can be effectively used in the case of slightly applying a plating inhibiting material, such as an SAM-forming molecular species (ink 121), to the interior surfaces 111b of the recesses 111c such as fine trenches, i.e., in the case of applying a plating inhibiting material (ink 121) to the outermost surface 111a of the substrate 111 and, in addition, also to those portions of the interior surfaces 111b of the recesses 111c such as fine trenches which lie in the vicinity of the outermost surface 111a of the substrate 111. A plating inhibiting film such as SAM can be formed on the substrate 111 by using an apparatus and method as described above.

Methods for forming the plating inhibiting material layer 123, i.e., a plating inhibiting film, on the outermost surface 111a of the substrate 111 have been described by referring to FIGS. 11 through 15. While an SAM (self-assembled molecular monolayer) has been described as an example of the plating inhibiting film, the plating inhibiting film is not limited to SAM.

When carrying out electro plating of the substrate 111 after forming a plating inhibiting film, such as SAM, on the outermost surface 111a by any of the above-described methods, formation of a plated film, i.e., deposition of a plated metal, is inhibited in the region where the plating inhibiting film such as SAM is formed, because such plating inhibiting film is an insulating material. Accordingly, plating can be carried out selectively. Since the plating inhibiting material layer (plating inhibiting film) 123 such as SAM is not formed on the interior surfaces 111b of the recesses 111c, such as fine trenches, formed in the surface of the substrate 111, plating can be effected selectively onto the interior surfaces 111b of the recesses 111c such as fine trenches.

Thus, the plating inhibiting material layer (plating inhibiting film) 123 such as SAM can be formed selectively on those raised portions of semiconductor interconnects which are to be removed in a post-damascene plating step, i.e., on the barrier layer 122 of e.g., ruthenium whose surface is the outermost surface 111a of the substrate 111. Therefore, a plated film can be formed selectively in the recesses 111c such as trenches of the substrate 111 in later electroplating. Accordingly, the surface after plating is flatter over the entire substrate as compared to the case of not forming a plating inhibiting film such as SAM and, in addition, the plated film formed on the outermost surface 111a of the substrate 111 is thin. This can shorten the polishing time in a later CMP step.

By controlling the amount of the plating inhibiting material covering the substrate 111, in particular the amount of the plating inhibiting material per unit area of the outermost surface 111a of the substrate 111, it becomes possible to form a plated film also in the portion covered with the plating inhibiting material while controlling the speed of the growth of plated film. Accordingly, post-plating heat treatment can attain the intended effects, such as re-crystallization and a reduction of strain of the plated film, providing the plated film with more desirable physical properties for interconnects. In this connection, in case a plated film is formed only on the interior surfaces 111b of the fine recesses 111c such as trenches, i.e., only inside the recesses, the stain reduction effect of heat treatment is small because of the small volume of the plated film formed. By effecting plating also in the portion covered with a plating inhibiting film, a plated film integrated with the plated film in fine recesses and having a large volume as a whole, can be formed. Accordingly, the stain reduction effect, etc. of heat treatment can be enhanced. This can eliminate the problem of interfacial separation between e.g., a copper film, a barrier layer and a low-k material layer.

[Method for Removing Plating Inhibiting Material]

The following methods (1) to (5) can be used to remove (release) the ink 121 attached to the outermost surface 111a of the substrate 111:

(1) A method of releasing the plating inhibiting material (ink) 121 from the outermost surface 111a of the substrate 111 by carrying out a reverse-electrolysis processing with reverse polarity to that of electroplating when the surface of a plated metal, such as copper, which has been filled into the recesses 111c by electroplating, has reached the same level as the outermost surface 111a of the substrate 111 to which the plating inhibiting material (ink) 121 has been attached.

(2) A method of releasing the plating inhibiting material from the outermost surface 111a of the substrate 111 in or outside a plating solution by an elastic body having such physical properties as not to damage the substrate, for example, a non-woven fabric or a pad of rubber, polyurethane, acrylic resin, etc. when the surface of a plated metal, such as copper, which has been filled into the recesses 111c by electroplating, has reached the same level as the outermost surface 111a of the substrate 111 to which the plating inhibiting material has been attached.

(3) A method of releasing the plating inhibiting material from the outermost surface 111a of the substrate 111 outside a plating solution by immersing the substrate 111 in an organic solvent or an acidic or alkaline aqueous solution, which dissolves the plating inhibiting material, when the surface of a plated metal, such as copper, which has been filled into the recesses 111c by electroplating, has reached the same level as the outermost surface 111a of the substrate 111 to which the plating inhibiting material has been attached.

(4) A method of releasing the plating inhibiting material from the outermost surface 111a of the substrate 111 in or outside a plating solution by ultrasonically vibrating the outermost surface 111a with an ultrasonic transducer when the surface of a plated metal, such as copper, which has been filled into the recesses 111c by electroplating, has reached the same level as the outermost surface 111a of the substrate 111 to which the plating inhibiting material has been attached.

(5) A method of releasing the plating inhibiting material from the outermost surface 111a of the substrate 111 in or outside a plating solution by applying a water pressure to the outermost surface 111a by a nozzle or the like when the surface of a plated metal, such as copper, which has been filled into the recesses 111c by electroplating, has reached the same level as the outermost surface 111a of the substrate 111 attached the plating inhibiting material.

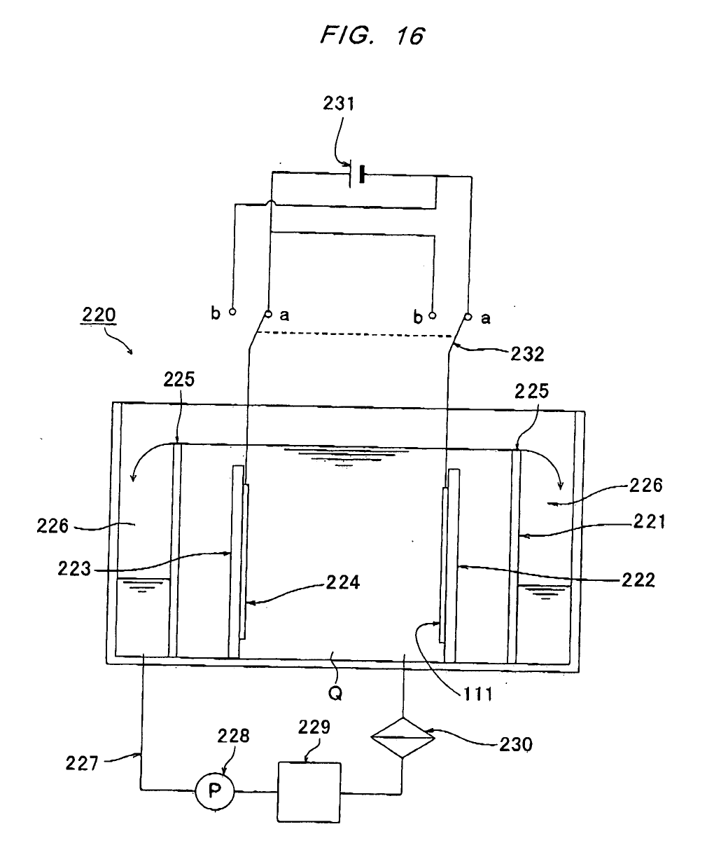

A substrate processing method of the present invention will now be described by mainly illustrating a copper electroplating step. FIG. 16 shows a substrate processing apparatus according to the present invention. The substrate processing apparatus 220 is an electroplating apparatus and includes a plating tank 221 for holding a plating solution (copper sulfate-plating solution) Q. A substrate 111 held by a substrate holder 222 and an anode 224 held by an anode holder 223 are disposed opposite to each other in the plating tank 221. An overflow tank 226 is disposed outside the plating tank 221, so that the plating solution Q overflowing an overflow weir 225 of the plating tank 221 flows into the overflow tank 226.

The plating solution Q that has flowed into the overflow tank 226 is circulated by a pump 228 in the following manner: the plating solution Q is passed through a constant-temperature unit 229 and a filter 230, both provided in a circulation pipe 227, and supplied into the plating tank 221. The temperature of the plating solution Q from the overflow tank 226 is adjusted to a predetermined temperature in the constant-temperature unit 229, and contaminants are removed from the plating solution Q with the filter 230 before the plating solution Q is supplied into the plating tank 221. The substrate processing apparatus 220 includes a switching section (selector switch, etc.) 232. When the connecting terminals of the switching section 232 are in contact with contacts “a”, “a” of a plating power source (direct-current power source) 231, the cathode of the plating power source 231 is connected to the substrate 111 and the anode to the anode 224, and a voltage of negative polarity is applied to the substrate 111 and a voltage of positive polarity to the anode 224. When the connecting terminals of the switching section 232 are in contact with contacts “b”, “b” of the plating power source 231, the anode of the plating power source 231 is connected to the substrate 111 and the cathode to the anode 224, and a voltage of positive polarity is applied to the substrate 111 and a voltage of negative polarity to the anode 224.

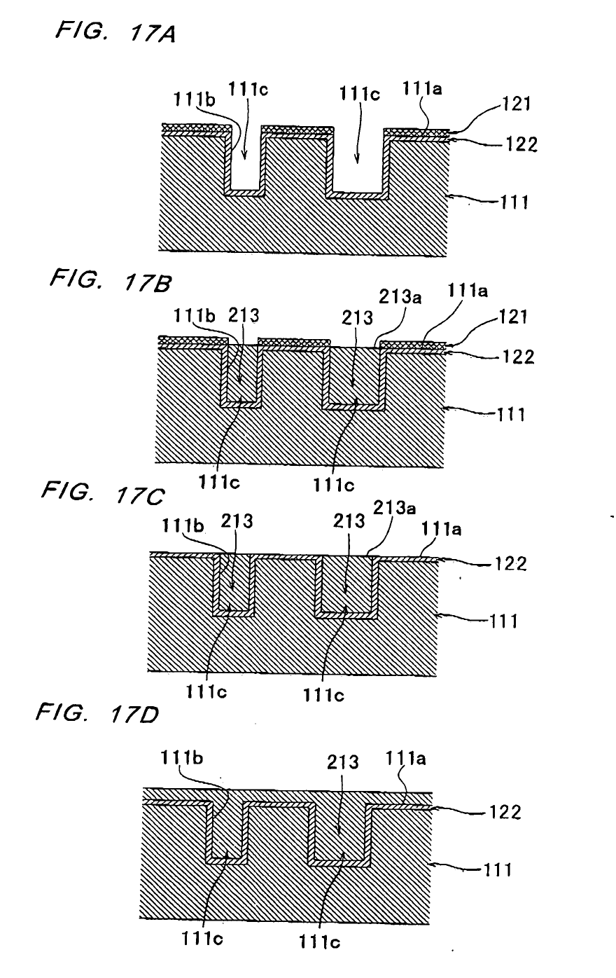

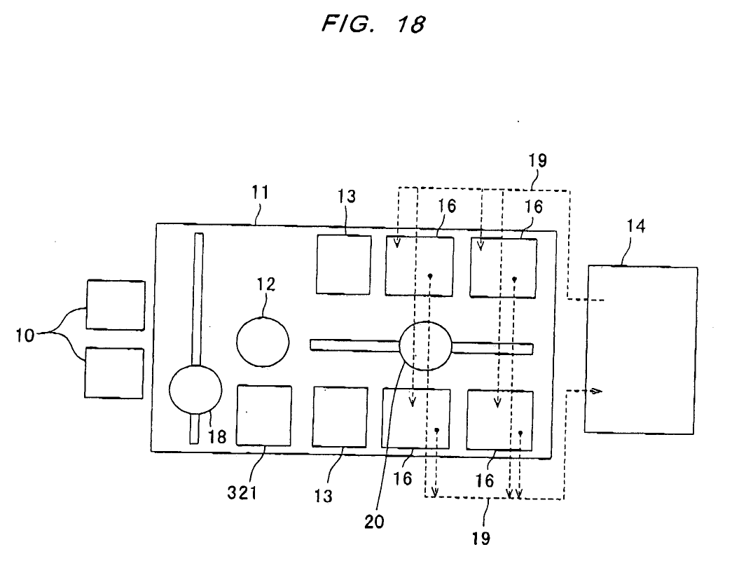

A process of processing a substrate by the substrate processing apparatus 220 having the above construction will be described with reference to FIG. 17. FIG. 17 illustrates the progress of plating on a substrate in a plating step according to the present invention. As shown in FIG. 17A, a substrate 111 with an ink 121 attached to the outermost surface 111a (the surface of barrier layer 122) of the substrate 111, i.e., the surface of the substrate 111 excluding the interior surfaces 111b of recesses 111c, such as trenches and contact holes, formed in the surface, is held by the substrate holder 222 such that the surface of the substrate 111 faces the anode 224. Thereafter, the connecting terminals of the switching section 232 are brought into contact with the contacts “a”, “a” of the plating power source 231, thereby applying a voltage of negative polarity from the plating power source 231 to the substrate 111 and a voltage of positive polarity to the anode 24 to initiate electroplating. During electroplating, a plated metal 213, copper in this case, deposits in the recesses 111c of the substrate 111. When the surface 213a of the plated metal (copper) 213 deposited in the recesses 111c has reached the level of the outermost surface 111a of the substrate 111 to which the ink 121 is adhering, i.e., the outmost surface of the outermost barrier layer 122, as shown in FIG. 17B, the connecting terminals of the switching section 232 are disconnected from the contacts “a”, “a” of the power source 231 to stop electroplating.

Thereafter, the connecting terminals of the switching section 232 are brought into contact with the contacts “b”, “b” of the plating power source 231, thereby applying a voltage of positive polarity from the power source 231 to the substrate 111 and a voltage of negative polarity to the anode 224 to carry out reverse-electrolysis processing with reverse polarity to that of the electroplating for a predetermined time. By the reverse-electrolysis processing, the ink 121 adhering to the outermost surface 111a of the substrate 111 is removed, whereby the outermost surface 111a of the substrate 111 becomes flush with the surface of the plated metal (copper) 213, as shown in FIG. 17C. Next, the connecting terminals of the switching section 232 are brought into contact with the contacts “a”, “a” of the plating power source 231 to carry out electroplating for a predetermined time, thereby depositing a flat plated metal (copper) 213 over the entire surface of the substrate 111, as shown in FIG. 17D.

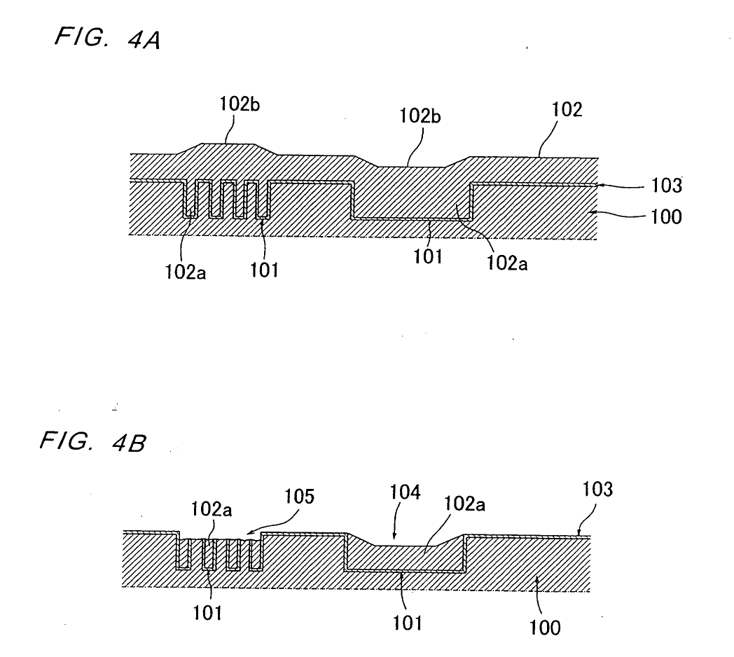

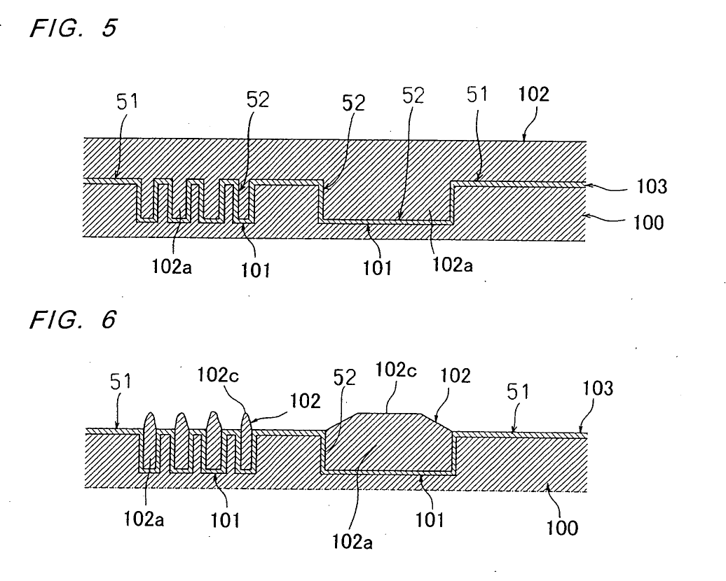

When the substrate 111 with the flat deposition layer of the plated metal (copper) 213 formed on the entire surface of the substrate 111 is heat-treated in a step after the above plating step, sufficient re-crystallization and a reduction of strain of the plated metal can be effected, thereby preventing the occurrence of troubles, such as disconnection in interconnects. Further, by controlling the thickness of the deposition layer of the plated metal (copper) 213 at an appropriate value, the time taken for CMP processing can be controlled at a proper time. In a CMP step, an extra plated metal (copper) 213 can be removed while achieving flattening of the entire substrate 111. Further, CMP can be carried out suitably without causing problems such as dishing 104 and erosion 105 (see FIG. 4B), and separation between copper, the barrier layer and an insulating film.

### EXPERIMENTAL EXAMPLE

An experimental example will now be described in which a copper film is formed by copper electroplating on a semiconductor wafer by using a substrate processing method and a plating inhibiting material-transferring stamp according to the present invention. A two-component room temperature-curing silicone rubber (trade name Silpot 184W/C), manufactured by Dow Corning Corp., was used for a stamp.

An 8-inch Si wafer with SiO₂ oxide film (first wafer) was used as the support 132 of the stamp 133. The wafer was cleaned by UV ozone cleaning, and a primer (FSXA-2869, Dow Corning Corp.) was applied to the mirror surface of the wafer. Subsequently, the above Silpot 184W/C, after mixing and defoaming under reduced pressure, was applied dropwise onto the first wafer. Thereafter, a separate 8-inch wafer with the oxide film (second wafer) was superimposed on the first wafer, without using a primer, such that its mirror surface comes into contact with the silicone rubber (Silpot 184W/C). The combined wafers were left to stand at room temperature for about 24 hours or for a predetermined time in a constant-temperature bath (e.g., at 150° C. for about one hour) to cure the silicone rubber.

After curing of the silicone rubber, the separate 8-inch wafer without a primer (second wafer) was peeled off from the silicone rubber, and the wafer with the silicone rubber attached with a certain thickness (first wafer) was used as a stamp.

Though after use of the stamp, the surface of the plating inhibiting material-carrying portion, i.e., the surface of the silicone rubber, may be cleaned with the same solvent as that of the ink used, it is cleaned by UV ozone cleaning for initial use of the stamp.

A solution of about 0.1 to 50 mmol/l of octadecyltrichlorosilane as a plating inhibiting material, i.e., as an ink (solute), in hexane or toluene as a solvent, or a solution of about 0.1 to 50 mmol/l of alkanethiol CₙH₂ₙ₊₁SH (n=8, n=10) as an ink in an alcohol solvent (ethyl alcohol, isopropyl alcohol or butyl alcohol), was used for transfer to an outermost surface of a substrate. An alkanethiol with a larger number of n, after it is attached to a metal surface, is more likely to come into a stable energy state with the attraction and the repulsion between the alkyl chains balanced due to van der Waals force. Such an alkanethiol can therefore be more easily attached to a substrate at a high density, and thus is preferred as an ink. An alkanethiol with a larger number of n, however, is less soluble in a solvent. Thus, the number of n is preferably in the range of 8-10.

The solution containing the ink was applied to the silicone rubber, the plating inhibiting material-carrying portion of the stamp, by using a spin coater.

The surface of the silicone rubber of the stamp was pressed against the ink-receiving surface of a semiconductor wafer with a copper seed layer formed, thereby transferring the solution containing the ink to the surface of the wafer. The contact time during transfer was suitably changed in the range of from 3 seconds to 2 minutes. The semiconductor wafer was immersed in a copper sulfate-plating solution within about one minute after the ink transfer to initiate copper electroplating. The following is an example of the composition of the copper sulfate-plating solution.

Composition of Copper Sulfate-Plating Solution

| | | |
|---|---|---|
| CuSO₄.H₂O | 225 | g/l |
| H₂SO₄ | 55 | g/l |
| Cl⁻ | 60 | ppm |

Electroplating was carried out at a current density on the semiconductor wafer of −5 to −50 mA/cm² until embedding the recesses of the semiconductor wafer with copper was completed.

After filling the recesses, such as trenches, with the plated metal (copper), reverse-electrolysis processing with reverse polarity to that of the electroplating was carried out. In particular, a voltage of positive polarity was applied to the semiconductor wafer at a current density of +5 to +50 nA/cm^{2 for} 10 millisecond to 5 second, thereby releasing the ink from the surface of the semiconductor wafer into the plating solution.

Thereafter, electroplating was again carried out under the above conditions. As a result of the sequence of processings, a thin flat film of the plated metal (copper film), having a thickness of several tens of nm on the outermost surface of the semiconductor wafer, was formed over the entire surface (i.e., the surface with the recesses such as trenches formed) of the semiconductor wafer.

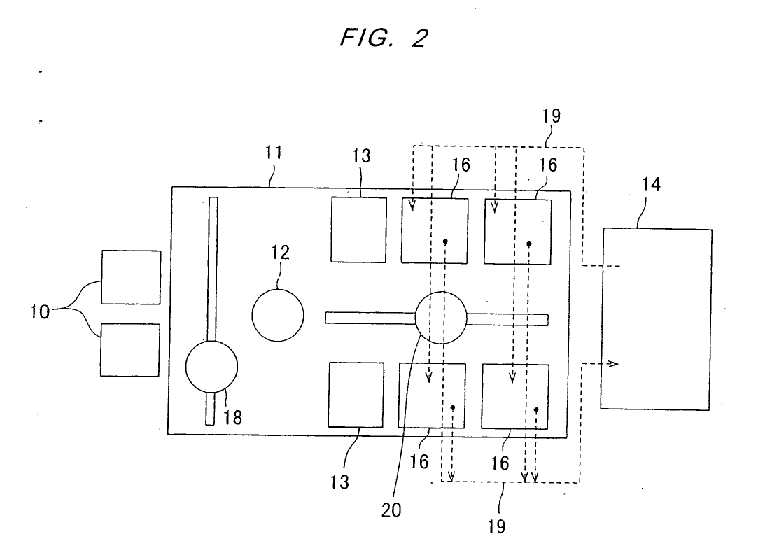

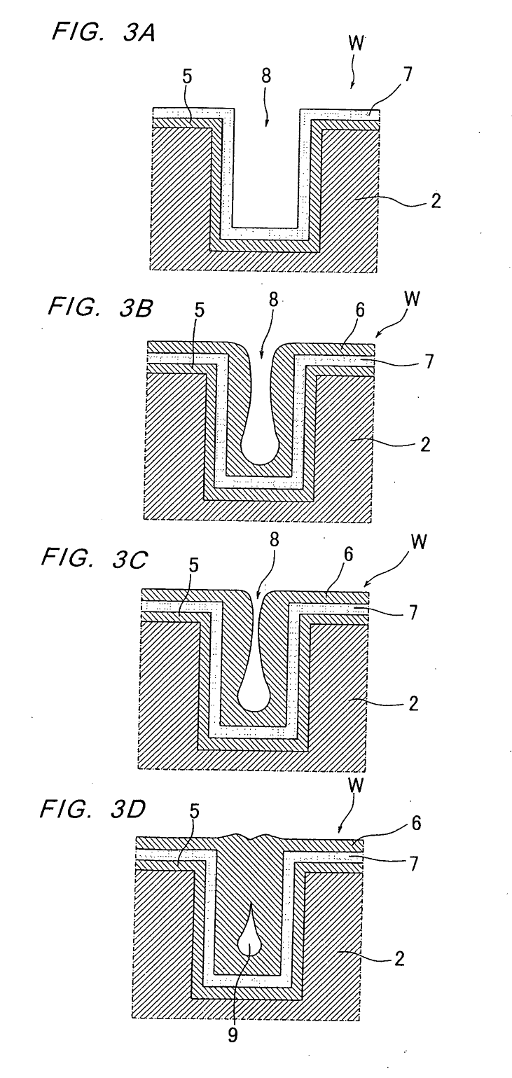

FIG. 18 is a diagram showing a layout of a substrate processing apparatus according to another embodiment of the present invention. In FIG. 18, the same reference numerals as FIG. 2 denote the same or corresponding components or elements. This substrate processing apparatus is the same as the substrate processing apparatus shown in FIG. 2 in that in the apparatus frame 11 are disposed a stand 12, two post-cleaning apparatuses 13 and four electroplating apparatuses 16 connected via piping 19 to a plating solution recovery apparatus 14, a first movable substrate transport robot 18 for transferring a substrate between the substrate cassette 10 and the stand 12, and a second movable substrate transport robot 20 for transferring the substrate between the stand 12, one of the post-cleaning apparatuses 13 and one of the electroplating apparatuses 16.

The present substrate processing apparatus differs from the substrate processing apparatus shown in FIG. 2 in that a liquid application/drying section 321 for applying a liquid containing a dissolved plating inhibiting material to a surface of a substrate with trenches and/or holes formed and then drying the substrate, is disposed between the first substrate transport robot 18 and one of the post-cleaning apparatuses 13.

In the substrate processing apparatus having the above construction, the substrate in a dry state, which has been taken by the first substrate transport robot 18 out of the substrate cassette 10 and placed on the stand 12, is transported by the second substrate transport robot 20 to the liquid application/drying section 321, where a liquid containing a dissolved plating inhibiting material is applied to the surface of the substrate with trenches and/or holes formed, followed by drying of the substrate. Thereafter, the substrate is transported to the electroplating apparatus 16, where electroplating of the substrate is carried out. The substrate after plating is transported to the post-cleaning apparatus 13, where the substrate is post-cleaned and dried, and the dried substrate is then placed on the stand 12. The substrate on the stand 12 is returned by the first substrate transport robot 18 to the substrate cassette 10.

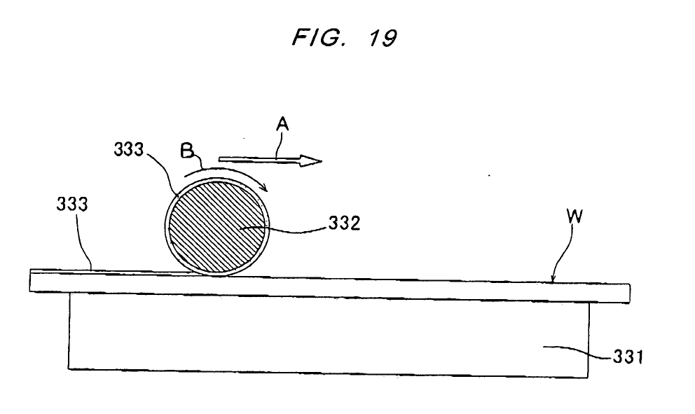

FIG. 19 schematically shows the construction of a liquid application section of the liquid application/drying section 321. The substrate W, such as a semiconductor wafer shown in FIG. 19, has a surface in which recesses, such as trenches and holes having a trench width or a hole diameter of 0.01 μm-200 μm, are formed. A barrier layer (not shown) for preventing diffusion of a conductive layer and a conductive material is formed on the surface (surface to be processed) of the substrate with the recesses formed. The substrate W is held on a substrate holder 331, for example, by attracting the non-processing surface (without recesses) of the substrate W to the substrate holder 331 comprised of an attraction chuck. A liquid 333 containing a dissolved plating inhibiting material is attached to the surface of a roller 332 for applying the liquid containing a dissolved plating inhibiting material to the substrate W. By moving the roller 332 on the substrate W in the direction of arrow A while rolling it as shown by arrow B, the liquid 333 is transferred or applied to the surface of the substrate W, forming a attached film of the liquid 333.

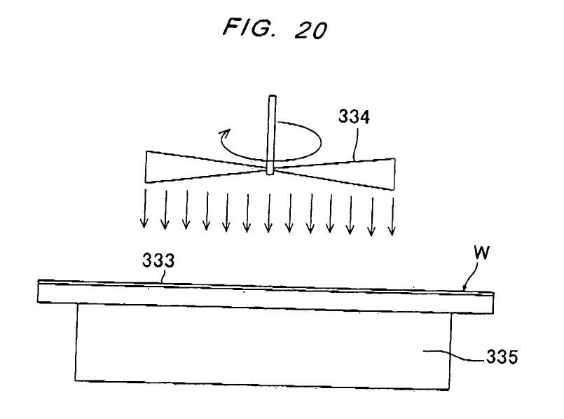

FIG. 20 shows a drying section of the liquid application/drying section 321 for drying the liquid 333 attached to the surface of the substrate W. The substrate W is held on the substrate holder 335, for example comprised of a vacuum-attraction chuck, with its non-processing surface attracted to the substrate holder 335 and its processing surface, to which the liquid 33 is attached, upward. A fan 334, for blowing hot air onto the surface of the substrate W with the liquid 333 on it, is disposed above the substrate holder 335. By blowing hot air from the fan 334 onto the surface of the substrate W, the solvent of the liquid 333 containing a dissolved plating inhibiting material evaporates, and only the plating inhibiting material remains on the surface of the substrate W.

After thus applying the liquid 333 containing a dissolved plating inhibiting material to the surface of the substrate W and drying the substrate W in the liquid application/drying section 321, the substrate W is transported by the second substrate transport robot 20 to the electroplating apparatus 16, where electroplating of the substrate W is carried out. The substrate W after plating is transported to the post-cleaning apparatus 13, where the substrate W is post-cleaned and dried, and the dried substrate W is placed on the stand 12. The substrate W on the stand 12 is then returned by the first substrate transport robot 18 to the substrate cassette 10.

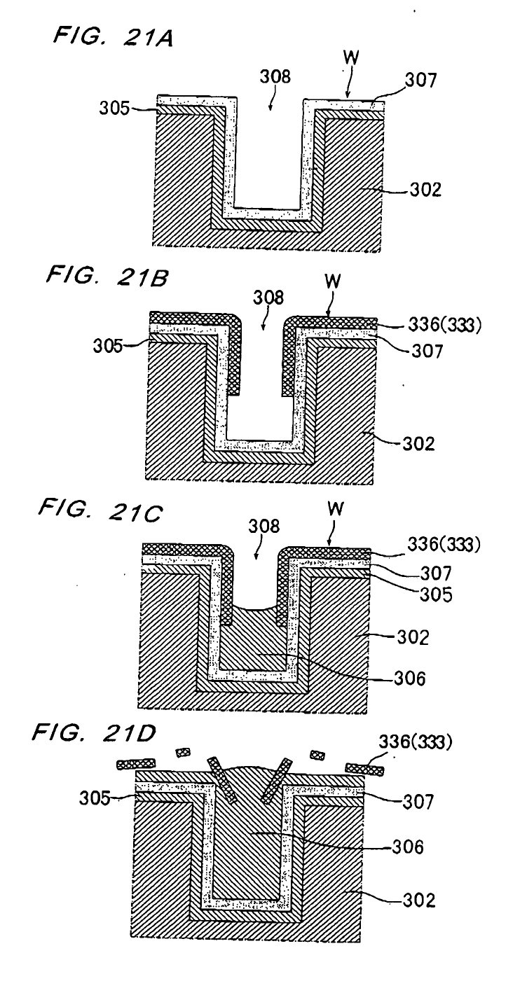

FIGS. 21A through 21E illustrate a process as carried out in the substrate processing apparatus according to the present invention. As shown in FIG. 21A, recesses 308, such as trenches and contact holes, are formed in an insulating film 302, such as an oxide film of SiO₂ or a film of low-k material. In the case of deep trenches or contact holes, an insulating film 302, such as an oxide film or a film of polyimide, is formed on the surfaces of the trenches or contact holes formed in the substrate. A barrier layer 305 and a seed layer 307 are formed on the surface of the insulating film 302. A liquid 333 containing a dissolved plating inhibiting material is applied to the surface of the substrate W, excluding the bottom surfaces and those portions of the side surfaces, which lie in the vicinity of the bottom surfaces, of the recesses 308. By subsequently drying the liquid 333, the solvent of the liquid 333 is removed, leaving only the plating inhibiting material 336, as shown in FIG. 21B.

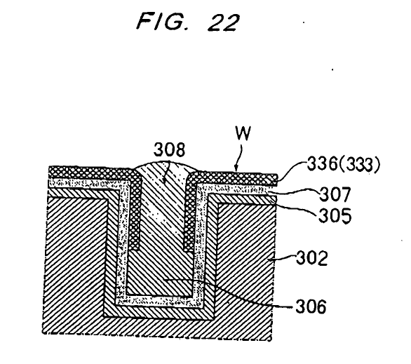

When carrying out electroplating with copper of the substrate W whose surface is covered with the plating inhibiting material 336, except for the bottoms of the recesses 308 and those portions of the side surfaces which lie in the vicinity of the bottom surfaces, by the electroplating apparatus 16, a copper film 306 is deposited on the bottom surfaces of the recesses 308 and those portions of the side surfaces which lie in the vicinity of the bottom surfaces, where the plating inhibiting material is absent, as shown in FIG. 21c. By continuing plating, the recesses 308 can be filled with the copper film 306 without forming voids in the embedded copper film 306, as shown in FIG. 22. When the copper film 306 has grown to reach the lower end of the plating inhibiting material 336 on the interior side surfaces of the recesses 308, as shown in FIG. 21C, reverse-electrolysis processing with reverse polarity to that of the electroplating is carried out, thereby breaking the plating inhibiting material 336 by dielectric breakdown. By again carrying out electroplating after the dielectric breakdown of the plating inhibiting material 336, a copper film 306 is formed on the entire surface of the seed layer 307 of the substrate W, as shown in FIG. 21D. The recesses 308, such as trenches and contact holes, formed in the surface of the substrate W, can thus be filled with the copper film 306 without a void.

A variety of materials can be used as a plating inhibiting material. In this embodiment, an adsorbent material such as alkanethiol, which is adsorbent to a substrate surface, is used as the plating inhibiting material 336, and a solution of the adsorbent material whose concentration is adjusted with a solvent, such as ethanol, is used as the liquid 333. A method for removing the plating inhibiting material 336 after the copper film 306 is deposited on the bottom surfaces of the recesses 308 and those portions of the side surfaces which lie in the vicinity of the bottom surfaces, as shown in FIG. 21C, is not limited to dielectric breakdown by reverse-electrolysis processing with reverse polarity to that of electroplating. It is also possible to remove the plating inhibiting material 336 by other physical or chemical method, for example, etching such as chemical etching, and to again carry out electroplating after the removal of the plating inhibiting material, thereby forming copper film 306 over the entire surface of the seed layer 307 of the substrate W, as shown in FIG. 21D.

Though, in this embodiment, the liquid application section of the liquid application/drying section uses the (cylindrical) roller 332, and transfers the liquid 333 containing a dissolved plating inhibiting material to the surface of the substrate W by applying the liquid 333 to the surface of the roller 332, and rolling the roller 332 on the surface of the substrate W, as shown in FIG. 19, the liquid application section is not limited to the use of such a roller. Thus, it is possible to use a movement mechanism which brings a flat or cylindrical application member into contact with a substrate W and moves the application member horizontally or vertically with respect to the substrate W. It is also possible to use a mechanism which brings a flat application member into contact with a surface of a substrate and rotates the application member, a spray mechanism which sprays a liquid onto a surface of a substrate, or a spin coating mechanism which applies a liquid dropwise onto a substrate while rotating the substrate, or a combination thereof. The depth of a plating inhibiting material, attached to the side surfaces of the recesses of a substrate, from the outermost surface of the substrate, can be controlled by adjusting the concentration of the plating inhibiting material in a liquid containing the material, the viscosity of the liquid, the amount of the liquid applied, etc. Since deposition of a plated metal can thus be inhibited to a desired depth, it is possible to select conditions that enable efficient plating without the formation of voids.

Though, in this embodiment, the drying section of the liquid application/drying section uses the fan 334, and dries a substrate (liquid 333) by blowing hot air onto the surface of the substrate, as shown in FIG. 20, the drying section is not limited to the use of such a fan. Thus, it is possible to use a method of heating and drying a substrate with a heating means (e.g., heater), a method of rotating a substrate with a rotating means so as to dry the substrate by centrifugal force, or a method of drying a substrate in a vacuum atmosphere, or a combination thereof.

Though, in this embodiment, the liquid application/drying section is provided with a substrate holder 331 or 335, which holds a substrate W by vacuum-attracting the non-processing surface of the substrate W, as a substrate holding mechanism, a substrate holding mechanism is not limited to such vacuum-attraction. Thus, it is possible to use a chucking mechanism for chucking a peripheral portion of a substrate. The liquid application/drying section includes a movement mechanism for horizontally moving, vertically moving and/or rotating a substrate held by a substrate holding mechanism.

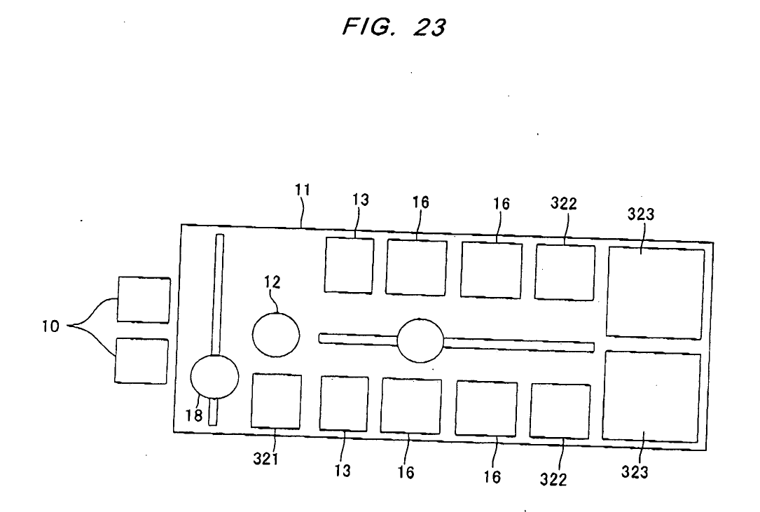

FIG. 23 is a diagram showing another layout of a substrate processing apparatus according to the present invention. In FIG. 23, the same reference numerals as FIGS. 2 and 21 denote the same or corresponding components or elements. This substrate processing apparatus differs from the substrate processing apparatus of FIG. 21 in that besides the four electroplating apparatuses 16 and two post-cleaning apparatuses 13, two cleaning apparatuses 322 and two CMP apparatuses 323 are provided as wet processing apparatuses. A depiction of a plating solution recovery apparatus and an abrasive liquid supply apparatus is omitted.

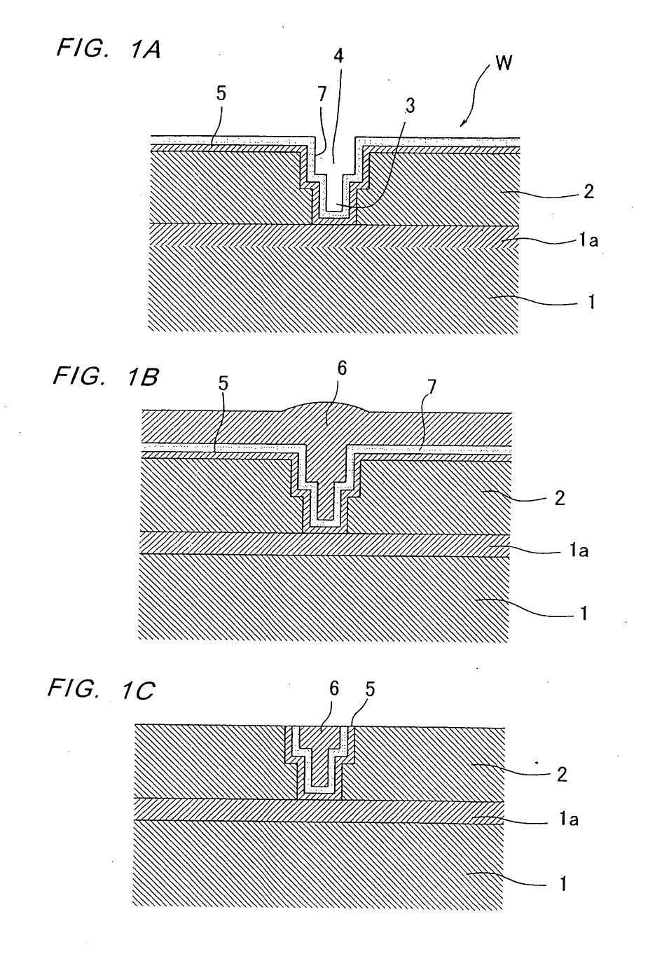

In this substrate processing apparatus having the above construction, the substrate in a dry state, which has been taken by the first substrate transport robot 18 out of the substrate cassette 10 and placed on the stand 12, is transported by the second substrate transport robot 20 to the liquid application/drying section 321, where a liquid containing a dissolved plating inhibiting material is applied to the substrate surface with trenches and/or holes (recesses) formed, followed by drying of the substrate. Thereafter, the substrate is transported to the electroplating apparatus 16, where electroplating of the substrate is carried out. The substrate after electroplating is cleaned in the cleaning apparatus 322, and then polished in the CMP apparatus 323 to remove the copper film, the barrier layer and the seed layer except those lying in the recesses 308 (see FIG. 1C). The substrate after polishing is transported to the post-cleaning apparatus 13, where the substrate is post-cleaned and dried, and then placed on the stand 12. The substrate on the stand 12 is then returned by the first substrate transport robot 18 to the substrate cassette 10.

Though the substrate processing apparatus of this embodiment includes, as wet processing apparatuses, the electroplating apparatus 16, the cleaning apparatus 322, the CMP apparatus 323 and the post-cleaning apparatus 13, the apparatus may further include as a wet processing apparatus at least one of an electrolytic etching apparatus, an electrolytic polishing apparatuses, a chemical etching apparatus and a cleaning apparatus. The liquid application/drying section 321 may be spatially isolated from a wet processing section in which the post-cleaning apparatuses 13, the electroplating apparatuses 16, the cleaning apparatuses 322 and the CMP apparatuses 323 are disposed (depiction omitted).

Though, in this embodiment, the liquid application/drying 321 is provided which carries out application of a liquid containing a dissolved plating inhibiting material to a substrate and drying of the applied liquid in a single unit, it is of course possible to provide a liquid application section and a drying section separately.

While the present invention has been described with reference to the embodiments thereof, it will be understood by those skilled in the art that the present invention is not limited to the embodiments, but changes could be made to the embodiments within the inventive concept that will be appreciated from the claims, the specification and the drawings. For example, though the case of carrying out electroplating with copper has been shown, the present invention is applicable to plating with other metal than copper.

1. A substrate processing method comprising:
preparing a substrate having recesses formed in a surface;
attaching a plating inhibiting material for inhibiting plating to an outermost surface, which excludes interior surfaces of the recesses, of the substrate surface; and then
carrying out electroplating of the surface of the substrate, thereby filling the recesses with a plated metal.

2. The substrate processing method according to claim 1, wherein after filling the recesses with the plated metal, the plating inhibiting material is released from the outermost surface of the substrate.

3. The substrate processing method according to claim 2, wherein after releasing the plating inhibiting material from the outermost surface of the substrate, additional electroplating is carried out on the surface of the substrate.

4. The substrate processing method according to claim 2, wherein the plating inhibiting material is released from the outermost surface of the substrate by a reverse-electrolysis processing with reverse polarity to that of the electroplating.

5. The substrate processing method according to claim 4, wherein the reverse-electrolysis processing with reverse polarity to that of the electroplating is carried out when the surface of the plated metal embedded in the recesses of the substrate has become flush with the outermost surface of the substrate to which the plating inhibiting material has been attached.

6. The substrate processing method according to claim 1, wherein the plating inhibiting material is attached to the outermost surface of the substrate by providing a stamp carrying the plating inhibiting material, and pressing the stamp against the surface of the substrate to transfer the plating inhibiting material carried on the stamp to the outermost surface of the substrate.

7. The substrate processing method according to claim 1, wherein the plated metal is copper, a copper alloy or silver.

8. The substrate processing method according to claim 1, wherein the plating inhibiting material is attached to the outermost surface of the substrate with a uniform thickness.

9. The substrate processing method according to claim 6, wherein a plating inhibiting material-carrying portion of the stamp for carrying the plating inhibiting material comprises at least one of a silicone resin and a fluorocarbon resin.

10. The substrate processing method according to claim 9, wherein the plating inhibiting material-carrying portion is supported by a support.

11. The substrate processing method according to claim 9, wherein at least an external surface of the plating inhibiting material-carrying portion is a flat plate-like or cylindrical face.

12. The substrate processing method according to claim 1, wherein the plating inhibiting material is attached to the outermost surface of the substrate by applying the plating inhibiting material in the form of a beam to the outermost surface approximately parallel thereto in a high-vacuum chamber at such a vacuum that the mean free path is equal to or longer than the distance from a plating inhibiting material jet orifice to the end of the substrate on the far side from the plating inhibiting material jet orifice.

13. The substrate processing method according to claim 12, wherein the plating inhibiting material is attached to the outermost surface of the substrate to form a self-assembled molecular monolayer.

14. The substrate processing method according to claim 13, wherein before attaching the plating inhibiting material to the outermost surface of the substrate, a metal is vapor-deposited onto the outermost surface of the substrate from a direction approximately parallel to the surface of the substrate in a high-vacuum chamber at a such a vacuum that the mean free path is equal to or longer than the distance from a vapor deposition source to the end of the substrate on the far side from the vapor deposition source.

15. The substrate processing method according to claim 14, wherein the metal is Au, Ag or Cu, or an alloy of two or three of the metals.

16. The substrate processing method according to claim 1, wherein a metal is vapor-deposited onto the outermost surface of the substrate from a direction approximately parallel to the surface of the substrate in a high-vacuum chamber at such a vacuum that the mean free path is equal to or longer than the distance from a vapor deposition source to the end of the substrate on the far side from the vapor deposition source, and then the plating inhibiting material is attached to the outermost surface of the substrate to form a self-assembled molecular monolayer.

17. The substrate processing method according to claim 16, wherein the metal is Au, Ag or Cu, or an alloy of two or three of the metals.

18. The substrate processing method according to claim 16, wherein the plating inhibiting material is attached to the outermost surface of the substrate by providing a stamp carrying the plating inhibiting material, and pressing the stamp against the surface of the substrate to transfer the plating inhibiting material carried on the stamp to the outermost surface of the substrate.

19. The substrate processing method according to claim 16, wherein the plating inhibiting material is transferred to the outermost surface of the substrate by screen printing using a screen for screen printing.

20. The substrate processing method according to claim 19, wherein a film composed of a mesh and a porous material is used as the screen for screen printing.

21. The substrate processing method according to claim 16, wherein the plating inhibiting material is transferred to the outermost surface of the substrate by pad printing.

22. The substrate processing method according to claim 1, wherein the plating inhibiting material is attached to the outermost surface of the substrate by screen printing using a screen for screen printing, thereby forming a self-assembled molecular monolayer.

23. The substrate processing method according to claim 22, wherein a film composed of a mesh and a porous material is used as the screen for screen printing.

24. The substrate processing method according to claim 1, wherein the plating inhibiting material is attached to the outermost surface of the substrate by pad printing, thereby forming a self-assembled molecular monolayer.

25. A plated film forming method for forming a plated metal on a surface of a substrate having a portion coated with a plating inhibiting material and a portion not coated with the material, comprising:
applying the plating inhibiting material in an amount corresponding to a desired plated thickness to an outermost surface of the substrate by a method according to claim 1;
carrying out plating to deposit a plated metal on the outermost surface of the substrate including interior surfaces of recesses; and
heat-treating the plated metal.

26. A substrate processing apparatus comprising:
a plating tank for holding a plating solution;
an anode disposed in the plating solution in the plating tank and opposite a substrate with a plating inhibiting material for inhibiting plating attached to an outermost surface of the substrate surface excluding interior surfaces of recesses; and
a plating power source for applying a predetermined plating voltage between the anode and the substrate.

27. The substrate processing apparatus according to claim 26, further comprising a polarity switching section for switching the voltage applied between the anode and the substrate so that the polarity is reversed.

28. A plating inhibiting material-transferring stamp for use in transferring a plating inhibiting material for inhibiting plating to an outermost surface of a substrate surface excluding interior surfaces of recesses formed in the substrate, when forming interconnects in the substrate by filling the recesses with a plated metal by electroplating, comprising
at least a plating inhibiting material-carrying portion of the stamp comprising at least one of a silicone resin and a fluorocarbon resin.

29. The plating inhibiting material-transferring stamp according to claim 28 further comprising a support for supporting the plating inhibiting material-carrying portion.

30. The plating inhibiting material-transferring stamp according to claim 28, wherein at least an external surface of the plating inhibiting material-carrying portion is a flat plate-like or cylindrical face.

31. A plating inhibiting material application apparatus for applying a plating inhibiting material to an outermost surface, which excludes interior surfaces of recesses, of a substrate surface to be plated, comprising:
a high-vacuum chamber;
a substrate holder, disposed in the high-vacuum chamber, for fixing the substrate;
a jet orifice, disposed in the high-vacuum chamber, for jetting the plating inhibiting material; and
a vacuum pump for vacuumizing the high-vacuum chamber.

32. A plating inhibiting material application apparatus for applying a plating inhibiting material to an outermost surface, which excludes interior surfaces of recesses, of a substrate surface to be plated, comprising:
a substrate holder for fixing the substrate;
a stamp for transferring and attaching the plating inhibiting material carried on the stamp to the outermost surface of the substrate by pressing the stamp against the surface of the substrate; and
a press mechanism for pressing the stamp against the surface of the substrate.

33. The plating inhibiting material application apparatus according to claim 32, wherein the portion of the stamp which is to be pressed against the surface of the substrate has a flat plate-like shape parallel to the surface of the substrate or a cylindrical shape whose axis is parallel to the surface of the substrate.

34. A plating inhibiting material application apparatus for applying a plating inhibiting material to an outermost surface, which excludes interior surfaces of recesses, of a substrate surface to be plated, comprising:
a substrate holder for fixing the substrate;
a screen;
a screen frame for fixing the peripheral portion of the screen; and
a squeegee, a tool for applying a pressure, which is to be moved in a direction parallel to the surface of the substrate while holding the plating inhibiting material between it and the screen and applying a pressure on the screen to press it against the surface of the substrate, so that by the pressure the screen is brought into sequential contact with the surface of the substrate and the plating inhibiting material is allowed to permeate the screen and to be attached to the surface of the substrate;
wherein the screen comprises two layers of a layer having a mesh structure and a layer comprising a porous elastic material, and the layer comprising the porous elastic material is disposed on the side to be brought into contact with the surface of the substrate when the pressure is applied by the squeegee.

35. A metal vapor deposition apparatus for vapor-depositing a metal onto an outermost surface, which excludes interior surfaces of recesses, of a substrate surface, comprising:
a high-vacuum chamber;
a substrate holder, disposed in the high-vacuum chamber, for fixing the substrate;
a vapor deposition source, disposed in the high-vacuum chamber, for melting a metal placed therein and generating vaporized particles of the metal;
a heater for heating the metal in the vapor deposition source; and
a vacuum pump for vacuumizing the high-vacuum chamber.

36. A substrate processing apparatus comprising:
a liquid application section for applying a liquid containing a dissolved plating inhibiting material to an outermost surface, which excludes interior surfaces of recesses, of a substrate surface;
a drying section for drying the liquid which has been applied to the substrate in the liquid application section; and
a plating section for carrying out plating of the substrate which has been dried in the drying section.

37. The substrate processing apparatus according to claim 36 further comprising a wet processing section comprised of at least one of a CMP apparatus, an electrolytic etching apparatus, an electrolytic polishing apparatus, a chemical etching apparatus and a cleaning apparatus.

38. The substrate processing apparatus according to claim 36, wherein the liquid application section applies the liquid to a surface of the substrate, the substrate surface excluding the bottom surfaces and those portions of the side surfaces which lie in the vicinity of the bottom surfaces of trenches and/or holes, having a trench width or hole diameter of 0.01 to 200 μm, provided in the surface of the substrate.

39. The substrate processing apparatus according to claim 36, wherein the liquid application section includes at least one of a movement mechanism for bringing a flat or cylindrical stamp for application of the liquid into contact with the substrate and moving the stamp horizontally or vertically with respect to the substrate, a mechanism for bringing a flat stamp into contact with the substrate and rotating the stamp, a rotating mechanism for bringing a cylindrical stamp into contact with the substrate and rotating the stamp, and a spray mechanism for spraying the liquid onto the surface of the substrate.

40. The substrate processing apparatus according to claim 36, wherein the liquid application section includes a substrate holder comprising a chucking mechanism for chucking a peripheral portion of the substrate or an attraction mechanism for attaching the non-processing surface of the substrate, and a movement mechanism for horizontally moving, vertically moving or rotating the substrate held by the substrate holder.

41. The substrate processing apparatus according to claim 36, wherein the drying section comprises at least one of a heating section for heating the substrate, an air-blowing section for blowing air onto the substrate, and a rotating section for rotating the substrate.

42. The substrate processing apparatus according to claim 36, wherein the liquid application section and the drying section are spatially isolated from a wet-processing section including the plating section.

43. A substrate processing method comprising:
applying a liquid containing a dissolved plating inhibiting material to an outermost surface, which excludes interior surfaces of recesses, of a substrate surface;
drying the liquid applied to the substrate; and
carrying out plating of the surface of the substrate after drying.

44. The substrate processing method according to claim 43 further carrying out at least one wet processing selected from CMP, electrolytic etching, electrolytic polishing, chemical etching, and cleaning.

45. The substrate processing method according to claim 43, wherein the liquid is applied to the substrate surface excluding the bottom surfaces and those portions of the side surfaces which lie in the vicinity of the bottom surfaces of trenches and/or holes, having a trench width or hole diameter of 0.01 to 200 μm, provided in the substrate surface.

46. The substrate processing method according to claim 43, wherein the liquid applied to the substrate is dried by heating the substrate, blowing air onto the substrate, or rotating the substrate.
